(19) United States
(12) Patent Application Publication
(10) Pub. No.: US 2010/0272895 A1
(43) Pub. Date: Oct. 28, 2010

(54) FILM DEPOSITION APPARATUS, FILM DEPOSITION METHOD, STORAGE MEDIUM, AND GAS SUPPLY APPARATUS

(75) Inventor: Einosuke Tsuda, Yamanashi-ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo (JP)

(21) Appl. No.: 12/680,088

(22) PCT Filed: Sep. 11, 2008
(86) PCT No.: PCT/JP2008/066455

§ 371 Date: Jun. 15, 2010

(30) Foreign Application Priority Data
Sep. 28, 2007 (JP) 2007-255780

(51) Int. Cl. C23C 16/06; C23C 16/00; C23C 16/44; C23C 16/52

(52) U.S. Cl. 427/255.32; 118/715; 427/255.28; 137/561 R; 118/697

(57) ABSTRACT

A film deposition apparatus comprises: a process container 2; a table 3 on which a substrate W can be placed, the table 3 being disposed in the process container 2; and a gas showerhead 4 disposed so as to be opposed to the table 3, the gas showerhead 4 including a gas supply surface 40a having a first gas supply hole 51b for supplying a first process gas, a second gas supply hole 52b for supplying a second process gas, and a third gas supply hole 53b for supplying a third process gas. The gas supply surface 40a is divided into unit zones 401 formed of regular triangles of the same size, and the first gas supply hole 51b, the second gas supply hole 52b, and the third gas supply hole 53b are disposed on respective three apexes of each regular triangle constituting the unit zone. The first process gas, the second process gas, and the third process gas differ from each other, and a film is deposited on a surface of the substrate W by reacting the first process gas, the second process gas, and the third process gas with each other.

### CROSS REFERENCE TO RELATED APPLICATIONS

This application is based upon and claims the benefit of priority from the prior Japanese Patent Application No. 2007-255780 filed on Sep. 28, 2007, the entire contents of which are incorporated herein by reference.

### FIELD OF THE INVENTION

The present invention relates to a technique for supplying a process gas to a substrate, so as to deposit a film of reaction products of the process gas on the substrate.

### BACKGROUND ART

As a film deposition method in a semiconductor manufacturing process, there has been known a method for depositing a film on a substrate, which makes, under vacuum atmosphere, a semiconductor wafer (hereinafter referred to as “wafer”), which is a substrate, adsorb a first process gas (material gas) on its surface, then switches a gas to be supplied from the first process gas to a second process gas (oxidizing gas) so as to form one or more atomic layers and molecular layers by the reaction of the first and second gases, and repeats this cycle plural times so as to stack these layers. This film deposition method, which is referred to as, e.g., an ALD (Atomic Layer Deposition) method or an MLD (Molecular Layer Deposition) method, can precisely control a film thickness depending on the number of cycles, and can provide an excellent film quality, i.e., a high in-plane uniformity. Thus, such a film deposition method is an effective method capable of coping with a thinner film of a semiconductor device.

For example, 3P2004-6733 A (particularly paragraph 0056 and FIG. 8) describes a film deposition apparatus for carrying out this film deposition method, wherein a film is deposited on a surface of a substrate placed in a process container (vacuum container) by alternately flowing two kinds of process gases from a left side surface of the process container to a right side surface thereof (or from the right side surface to the left side surface). When there is employed such a side flow method in which a process gas is flown from one side to the other side of a substrate, a lateral non-uniformity of a film thickness and of a film quality can be restrained. Thus, such a film deposition process can be performed under a relatively low temperature atmosphere such as about 200° C.

On the other hand, when a high dielectric constant material such as zirconium oxide (ZrO₂) is deposited, for example, a TEMAZ (tetrakis ethyl methyl amino zirconium) gas is used as the first process gas (material gas), and an ozone gas is used as the second process gas (oxidizing gas). Since a decomposition temperature of the TEMAZ gas is high, a film deposition process is performed at a temperature as high as, e.g., 280° C. However, under this high temperature condition, since a reaction speed is accelerated, a film thickness of a film deposited during one cycle tends to be thicker. In particular, in the side flow method, since a moving distance of a gas on the surface of the substrate is long, there is a possibility that a film thickness might be large on a gas supply side, but might be small on an exhaust side. In this case, an excellent in-plane uniformity of the film thickness cannot be obtained.

In addition, when a supply time of an ozone gas as an oxidizing gas is reduced in order to improve a throughput, for example, an oxidation ability of the ozone gas becomes weaker as a supply point becomes distant from a supply source of the ozone gas (ozone gas is consumed). Thus, there is a possibility that the high dielectric constant material adsorbed on the substrate might not be oxidized in a sufficiently uniform manner. In this case, values of a leak current of semiconductor devices formed in the wafer may be deviated.

In order to solve the disadvantage of the side flow method, the following method is under review. Namely, by using a gas showerhead (see, JP2006-299294A (particularly paragraphs 0021 to 0026)) for use in a general CVD apparatus, for example, a process gas is supplied from above a central part of a substrate, and a non-reacted process gas and a reaction byproduct are discharged from a bottom part of a process container. In this gas supply and discharge method, the process gas to be supplied flows from the center of the substrate toward a periphery thereof. Thus, since a moving distance of the gas is shorter than that in the side flow method, a high in-plane uniformity of a film thickness and of a film quality of the deposited film can be expected after the film deposition.

In order to further improve properties of a film in a device, a material of the film itself and a material gas have been selected and developed. As a material for a high dielectric constant film used for a gate oxide film, the present inventors have taken notice of oxides containing strontium (Sr) and titanium (Ti). The use of three kinds of gases as material gases, i.e., a material gas containing Sr compound, a material gas containing Ti compound, and an oxidizing gas has been under review. When a film is deposited by the ALD method by using a gas showerhead as described above, the gas showerhead should be a showerhead of a post-mix type in which the respective gases are allocated to a number of gas supply holes formed in a gas supply surface, so that the three kinds of gases are independently jetted.

On the other hand, in order to cope with the demand for thinner film, higher degree of integration, and higher performance of a semiconductor device, an excellent in-plane uniformity of a film thickness and of a film quality is required. Thus, how such an excellent in-plane uniformity is achieved should be researched, when the three kinds of gases are used.

JP2005-723A (see, paragraph 0052 and FIG. 4) describes a gas supply system wherein a gas supply surface of a gas showerhead is divided into unit zones formed of regular triangles of the same size, and gas supply holes are positioned on three apexes of each regular triangle constituting the unit zone. However, JP2005-723A does not describe the above object at all.

### DISCLOSURE OF THE INVENTION

The present invention has been made in view of the aforementioned circumstances. The object of the present invention is to provide a film deposition apparatus, a film deposition method, a storage medium storing this method, and a gas supply apparatus, capable of achieving an excellent in-plane uniformity of a film thickness and of a film quality, when three kinds of process gases are supplied to a substrate from a gas supply surface opposed to the substrate so as to deposit a film on the substrate.

A film deposition apparatus of the present invention comprising:

a process container;

a table on which a substrate can be placed, the table being disposed in the process container; and

a gas showerhead disposed so as to be opposed to the table, the gas showerhead including a gas supply surface having a first gas supply hole for supplying a first process gas, a second gas supply hole for supplying a second process gas, and a third gas supply hole for supplying a third process gas;

wherein:

the gas supply surface is divided into unit zones formed of regular triangles of the same size, and the first gas supply hole, the second gas supply hole, and the third gas supply hole are disposed on respective three apexes of each regular triangle constituting the unit zone; and

the first process gas, the second process gas, and the third process gas differ from each other, and a film is deposited on a surface of the substrate by reacting the first process gas, the second process gas, and the third process gas with each other.

In the film deposition apparatus of the present invention, it is preferable that

the first process gas supplied from the first gas supply hole contains a strontium compound;

the second process gas supplied from the second gas supply hole contains a titanium compound;

the third process gas supplied from the third gas supply hole is an oxidizing gas reactable with the strontium compound and the titanium compound; and

the film to be deposited on the surface of the substrate is made of strontium titanate.

In the film deposition apparatus of the present invention, it is preferable that

the oxidizing gas is an ozone gas or a steam.

A film deposition method of the present invention comprising the steps of:

placing a substrate on a table disposed in a process container; and

supplying gases from a gas showerhead disposed so as to be opposed to the table, the gas showerhead being divided into unit zones formed of regular triangles of the same size, with a first gas supply hole, a second gas supply hole, and a third gas supply hole being disposed on respective three apexes of each regular triangle constituting the unit zone;

wherein:

the step of supplying gases includes a first process-gas supplying step for supplying the first process gas, a second process-gas supplying step for supplying the second process gas, and a third process-gas supplying step for supplying the third process gas; and

the first process gas, the second process gas, and the third process gas differ from each other, and a film is deposited on a surface of the substrate by reacting the first process gas, the second process gas, and the third process gas with each other.

In the film deposition method of the present invention, it is preferable that

the first process gas supplied in the first process-gas supplying step contains a strontium compound;

the second process gas in the second process-gas supplying step contains a titanium compound;

the third process gas supplied in the third process-gas supplying step is an oxidizing gas reactable with the strontium compound and the titanium compound; and

the film made of strontium titanate is deposited on the surface of the substrate.

In the film deposition method of the present invention, it is preferable that

the oxidizing gas is an ozone gas or a steam.

A storage medium of the present invention storing a computer program for causing a film deposition apparatus to perform a film deposition method that comprises the steps of:

placing a substrate on a table disposed in a process container; and

supplying gases from a gas showerhead disposed so as to be opposed to the table, the gas showerhead being divided into unit zones formed of regular triangles of the same size, with a first gas supply hole, a second gas supply hole, and a third gas supply hole being disposed on respective three apexes of each regular triangle constituting the unit zone;

wherein:

the step of supplying gas includes a first process-gas supplying step for supplying the first process gas, a second process-gas supplying step for supplying the second process gas, and a third process-gas supplying step for supplying the third process gas; and

the first process gas, the second process gas, and the third process gas differ from each other, and a film is deposited on a surface of the substrate by reacting the first process gas, the second process gas, and the third process gas with each other.

A gas supply apparatus of the present invention comprising:

a first introduction port for introducing a first process gas;

a second introduction port for introducing a second process gas;

a third introduction port for introducing a third process gas;

a first gas supply hole for supplying the first process gas introduced from the first introduction port to a substrate;

a second gas supply hole for supplying the second process gas introduced from the second introduction port to the substrate;

a third gas supply hole for supplying the third process gas introduced from the third introduction port to the substrate; and

a gas conduit structure part configured such that the first process gas introduced from the first introduction port, the second process gas introduced from the second introduction port, the third process gas introduced from the third introduction port, are respectively jetted from the first gas supply hole, the second gas supply hole, and the third gas supply hole, independently;

wherein:

the first gas supply hole, the second gas supply hole, and the third gas supply hole are disposed in a gas supply surface;

the gas supply surface is divided into unit zones formed of regular triangles of the same size, and the first gas supply hole, the second gas supply hole, and the third gas supply hole are disposed on respective three apexes of each regular triangle constituting the unit zone; and

the first process gas, the second process gas, and the third process gas differ from each other, and a film is deposited on a surface of the substrate by reacting the first process gas, the second process gas, and the third process gas with each other.

In the present invention, the gas supply surface is divided into the unit zones formed of regular triangles of the same size. The first process gas, the second process gas, and the third process gas are supplied from the three apexes of each regular triangle. Thus, the three gas supply holes for jetting the first to third process gases exist in every regular triangle, and the three gas supply holes are arranged with equal intervals therebetween. Thus, when a film is deposited by the CVD method in which the first to third processing gases are jetted simultaneously or by the so-called ALD method in which those gases supply timings differ from each other, an excellent in-plane uniformity of a film thickness and of a film quality can be obtained.

### BRIEF DESCRIPTION OF THE DRAWINGS

FIG. 1 is a longitudinal sectional view of a film deposition apparatus in one embodiment.

FIG. 2 is an exploded perspective view of a gas showerhead disposed in the film deposition apparatus.

FIG. 3 is a longitudinal perspective view of the gas showerhead.

FIG. 4 is a longitudinal sectional view of the gas showerhead.

FIG. 5 is a longitudinal sectional view of a part of gas introduction conduits and gas supply conduits in the gas showerhead.

FIG. 6 is a view of gas supply paths in the film deposition apparatus.

FIG. 7 is a plan view showing an arrangement of gas supply holes formed in the gas showerhead.

FIG. 8 is an explanatory view of a transfer phenomenon of the gas supply holes.

FIG. 9 is an explanatory view showing process positions of a wafer in the film deposition apparatus.

FIG. 10 is an explanatory view showing an arrangement of the gas supply holes in this embodiment and an arrangement thereof in a comparative example.

FIG. 11 is a second explanatory view showing the above arrangements.

FIG. 12 is a first operational view of the film deposition apparatus.

FIG. 13 is a gas-supply sequence view in a film deposition process performed by the film deposition apparatus.

FIG. 14 is a second operational view of the film deposition apparatus.

FIG. 15 is a third operational view of the film deposition apparatus.

FIG. 16 is a fourth operational view of the film deposition apparatus.

FIG. 17 is a fifth operational view of the film deposition apparatus.

### BEST MODE FOR CARRYING OUT THE INVENTION

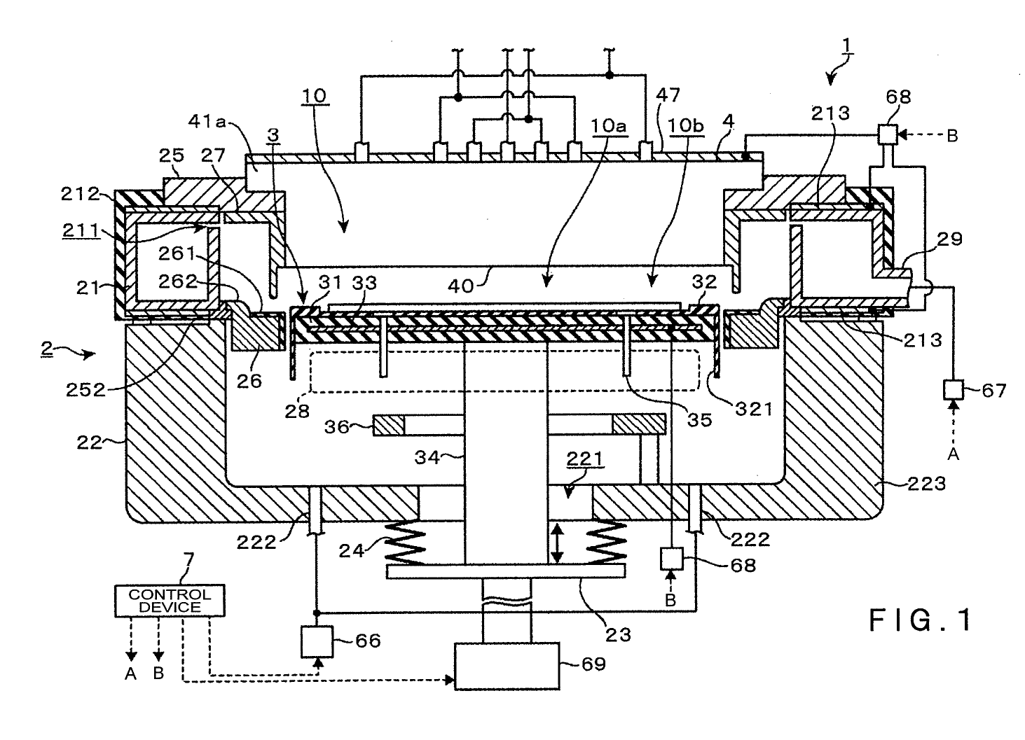

At first, an overall structure of the film deposition apparatus 1 in this embodiment is described with reference to FIG. 1. The film deposition apparatus 1 in this embodiment comprises: a process container 2 forming a vacuum container; a table 3 disposed in the process container 2, on which a wafer W as a substrate can be placed; and a gas showerhead 4 disposed on an upper part of the process container 2 so as to be opposed to the table 3, the gas showerhead 4 including a gas supply surface 40a provided with a first gas hole 51b through which a first process gas is supplied, a second gas supply hole 52b through which a second process gas is supplied, and a third gas supply hole 53b through which a third process gas is supplied.

The first process gas, the second process gas, and the third process gas differ from each other, and a thin film can be deposited on a surface of the wafer W by reacting these first process gases, the second process gas, and the third process gas with each other. For example, a material gas containing strontium (Sr) (hereinafter referred to as “Sr material gas”) may be used as the first process gas, a material gas containing titanium (Ti) (hereinafter referred to as “Ti material gas”) may be used as the second process gas, and an ozone gas which is an oxidizing gas may be used as the third process gas. By reacting the Sr material gas, the Ti material gas, and the ozone gas with each other, a film made of strontium titanate (SrTiO₃ (hereinafter abbreviated to “STO”), which is a high dielectric constant material, can be deposited on a surface of the wafer W by the ALD method.

The table 3 is composed of a stage 31 corresponding to a table body for supporting the wafer W, and a stage cover 32 for covering the stage 31. The stage 31 is made of aluminum nitride or quartz, and is formed to have a flat discoid shape. Embedded in the stage 31 is a stage heater 33 configured to heat a table surface of the table 3, so as to heat the wafer W to a film deposition temperature. The stage heater 33 is formed of, e.g., a sheet-like heating resistor, and is capable of heating the wafer W placed on the table 3 to, e.g., 280° C., by means of an electric power supplied from a power supply part 68. Further, an electrostatic chuck, not shown, is disposed in the stage 31. Thus, the wafer W placed on the table 3 can be electrostatically fixed.

On the other hand, the stage cover 32 constituting the table 3 together with the stage 31 has a function for preventing deposit of reactants such as reaction products and reaction byproducts onto the surface of the stage 31, by covering an upper surface and a side surface of the stage 31. The stage cover 32 is structured as a quartz removable cover member (called “deposit shield” or the like). A circular recess whose diameter is slightly larger than that of the wafer W is formed in a central area of an upper surface of the stage cover 32. Thus, the wafer W can be easily placed in position on the table surface above the stage cover 32.

The stage 3 is supported by a columnar support member 34 on a lower central part of the stage 31. The support member 34 is adapted to be vertically moved (moved upward and downward) (elevated and lowered) by an elevating mechanism 69. By vertically moving the support member 34, the table 3 can be vertically moved along a distance of 80 mm at maximum, between a transport position at which the wafer W is transported to and from an external transport mechanism, and a process position at which the wafer W is processed.

As shown in FIG. 1, the support member 34 passes through a bottom surface of the process container 2, in detail, a bottom surface of a lower container 22 described below, and is connected to an elevating plate 23 that is vertically moved by the aforementioned elevating mechanism 69. A space between the elevating plate 23 and the lower container 22 is hermetically sealed by a bellows 24.

In addition, the table 3 has a plurality of, e.g., three elevating pins 35 for vertically moving the wafer W on the table surface of the table 3 while supporting a rear surface of the wafer W. For example, as shown in FIG. 1, in a state where the table 3 is moved and located at the process position for the wafer W, the respective elevating pins 34 pass vertically through the stage 31 such that flat head parts of the elevating pins 35 stop at the upper surface of the stage 31, and that lower end parts thereof project from the bottom surface of the stage 31.

A ring-shaped elevating member 36 is disposed below the elevating pins 35 passing through the stage 31. In a state where the table 3 is lowered and located at the transport position for the wafer W, by vertically moving the elevating member 36 so as to vertically move the respective elevating pins 35, the wafer W supported by the elevating pins 35 can be vertically moved above the table surface of the table 3.

Openings for receiving the head parts of the elevating pins 35 are formed in the upper surface of the stage cover 32 at positions where the elevating pins 35 pass through. Thus, as shown in FIG. 1, when the table 3 is moved and located at the process position for wafer W, the upper surface of the stage cover 32 and the upper surfaces of the head parts of the respective elevating pins 35 are substantially coplanar with each other, whereby the flat table surface for the wafer W can be formed in the upper surface of the table 3. Further, a sidewall part of the stage cover 32 is extended below the stage 31 so as to form a skirt part 321 that surrounds an area below the stage 31 from a lateral side, so that the sidewall part and the body of the stage 31 integrally defines a side peripheral surface.

Next, a structure of the process container 2 is described. The process container 2 in this embodiment includes the flat bowl-like lower container 22, and an annular exhaust duct 21 superposed on the lower container 22. The lower container 22 is made of, e.g., aluminum. The lower container 22 has a through hole 221 in a bottom surface thereof, through which the support member 34 of the stage 31 can pass. A plurality of, e.g., four purge-gas supply conduits 222 are disposed around the through hole 221. Thus, a purge gas such as a nitrogen gas supplied from a purge-gas supply source 66 can be sent into the lower container 22. In FIG. 1, a transport opening 28, which is shown by the broken lines, can be opened and closed by a gate valve, not shown. The wafer W can be loaded unloaded through the transport opening 28 by the external transport mechanism.

The exhaust duct 21 is an annular member formed by curving an aluminum rectangular duct, for example. An inside diameter and an outside diameter of the annular body are substantially the same as an inside diameter and an outside diameter of the sidewall part 223 of the lower container 22. A wall surface of the exhaust duct 21, which is closer to the process atmosphere, is referred to as an inner wall surface, and a wall surface thereof, which is more distant from the process atmosphere, is referred to as an outer wall surface. In an upper end part of the inner wall surface, there are circumferentially arranged a plurality of vacuum exhaust ports 211, which are laterally extending slit-like exhaust ports, with intervals therebetween. An exhaust pipe 29 is connected to the outer wall surface of the exhaust duct 21 at one certain position, for example. By using a vacuum pump 67 connected to the exhaust pipe 29, for example, a gas can be discharged from the vacuum exhaust ports 211 so as to create a vacuum. As shown in FIG. 1, a heat insulation member 212 is disposed on the exhaust duct 21 such that an upper surface and a lower surface of the outer wall surface of the exhaust duct 21 are covered with the heat insulation member 212.

The exhaust duct 21 having the aforementioned structure is superposed on the lower container 22 via the heat insulation member 212. The exhaust duct 21 and the lower container 22, which are thermally insulated from each other, integrally constitute the process container 2. Since the plurality of vacuum exhaust ports 211 formed in the inner wall surface of the exhaust duct 21 are opened to a space including a process atmosphere 10, which is formed between the gas showerhead 4 and the table 3, the process atmosphere 10 can be discharged through the vacuum exhaust ports 211 to create a vacuum.

As shown in FIG. 1, disposed inside the process container 2 is an inner block 26 that separates, cooperatively with the table 3, a lower space which is a space inside the lower container 22, from an upper space located above the table 3. The inner block 26 is a ring-like member made of, e.g., aluminum, having such a size that the inner block 26 can be fit in a space between the inner wall surface of the sidewall part 223 of the lower container 22 and the side peripheral surface of the table 3. On an upper surface of an outer peripheral part of the inner block 26, there is disposed a projecting edge 262 that extends outward from the peripheral part. Due to an engagement of the projecting edge 262 with the intermediate ring body 252 provided between the sidewall part 223 of the lower container 22 and the lower end part of the inner wall surface of the exhaust duct 21, the inner block 26 is fixed in the process container 2.

As shown in FIG. 1, an area of the inner block 26, which extends from the upper surface to the inner peripheral surface of the inner block 26, is covered with a quartz block cover 261, whereby the deposit of the reactant onto the surface of the inner block 26 can be prevented. When the table 3 is located at the process position, the block cover 261 surrounds a side surface of the stage cover 32 (a side surface of the skirt part 361) with a 2 mm clearance therebetween, for example. Thus, a gas in the process atmosphere 10 is difficult to be diffused therefrom to the lower space.

In addition, a baffle ring 27 is disposed between the vacuum exhaust ports 211 formed in the inner wall surface of the exhaust duct 21 and the process atmosphere 10. The baffle ring 27 is a member having an inverted L-shape section, for lowering a flow conductance, to thereby allow the process container 2 to be uniformly exhausted in a circumferential direction thereof when viewed from the process atmosphere 10.

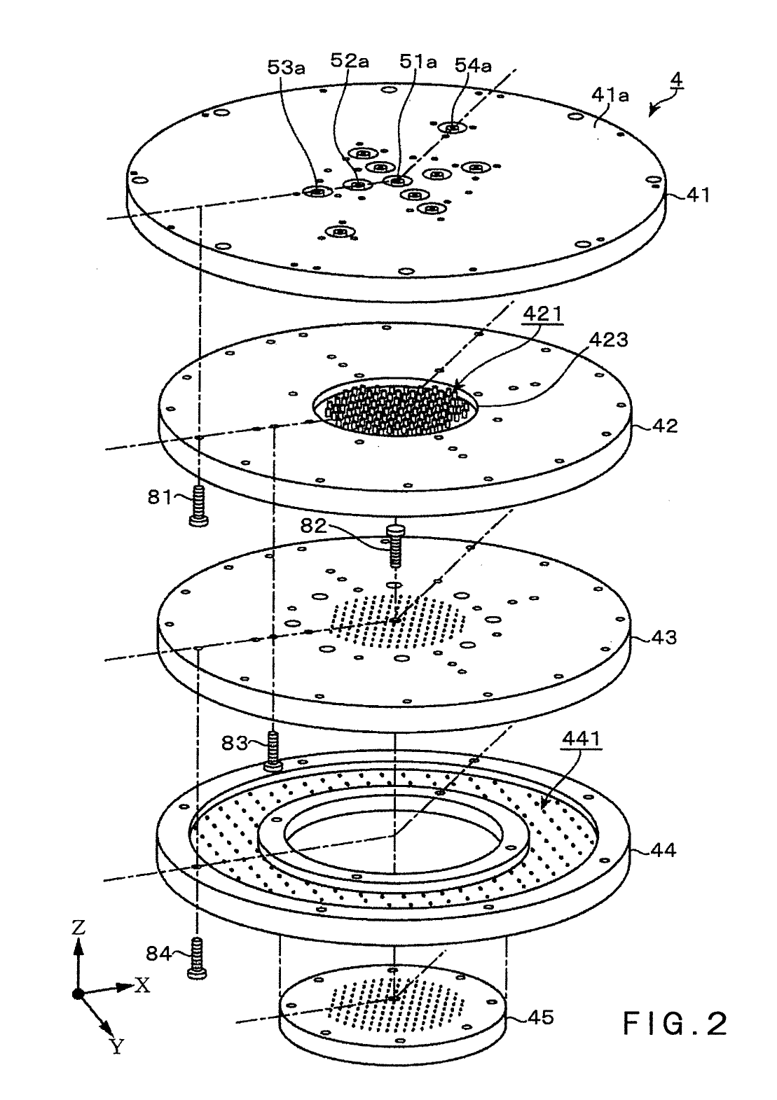

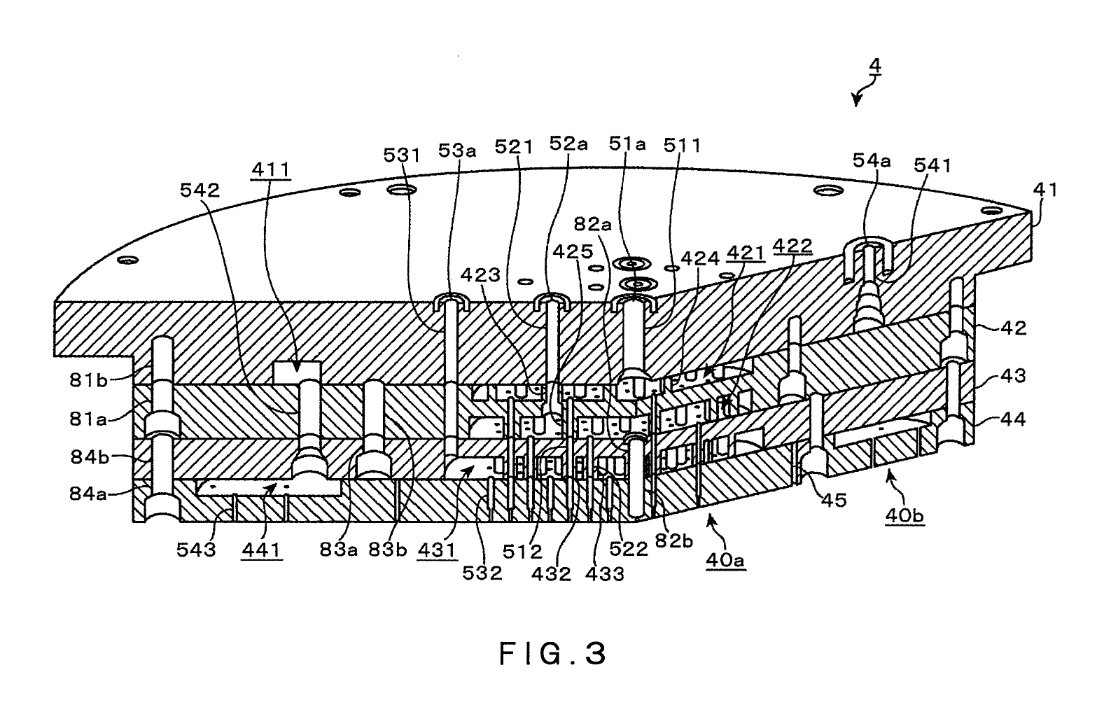

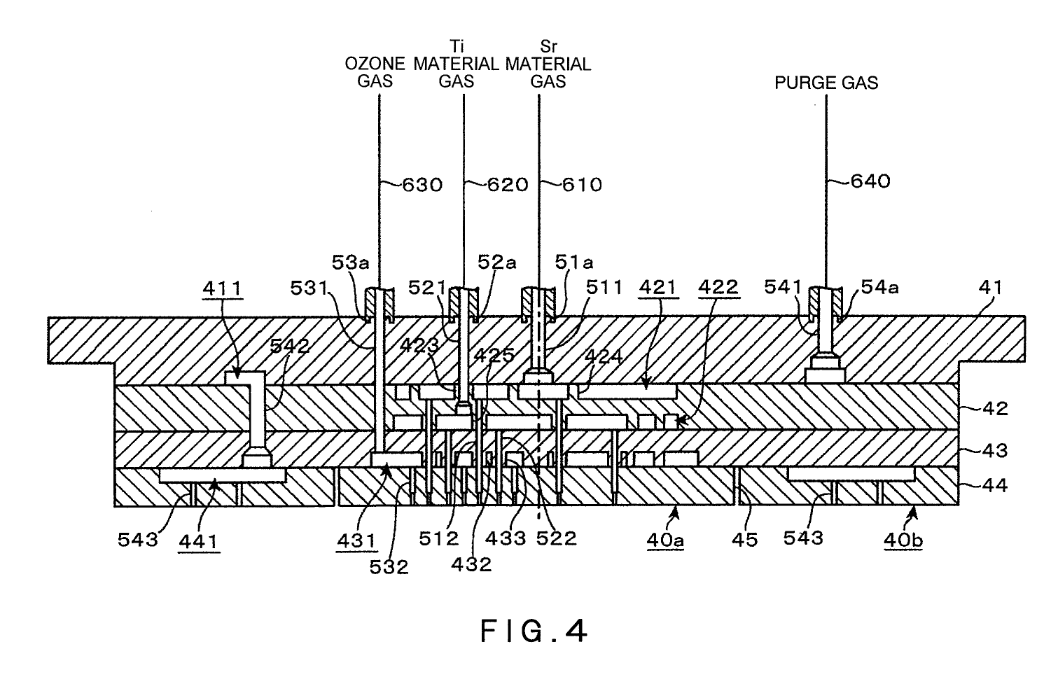

Next, the gas showerhead 4 is described. FIG. 2 is an exploded perspective view of the gas showerhead. FIGS. 3 and 4 are a longitudinal perspective view and a longitudinal sectional view of the gas showerhead 4 that is cut along the chain lines in FIG. 2. FIGS. 3 and 4 differ from each other in the right and left direction when viewed from a central position. The gas showerhead 4 in this embodiment is adapted to jet three kinds of process gases, i.e., a Sr material gas, a Ti material gas, and an ozone gas or purge gas, from a central area opposed to a central part of the wafer W placed on the table 3, to the process atmosphere 10. In addition, the gas showerhead 4 is adapted to jet the purge gas from a ring-shaped peripheral area surrounding the central area. In the central area of the gas showerhead 4, the gas showerhead 4 is structured as a gas showerhead of a so-called post mix type, which supplies the Sr material gas, the Ti material gas, and the ozone gas from gas supply holes which are exclusively used for the respective gases.

A supply structure of the process gases in the central area is described at first. As shown in FIGS. 3 and 4, a first introduction port 51a for introducing the Sr material gas, a second introduction port 52a for introducing the Ti material gas, and a third introduction port 53a for introducing the ozone gas, are formed in an upper surface of the gas showerhead 4. In addition to the aforementioned process gases, a purge gas can be supplied to these introduction ports 51a to 53a. Inside the gas showerhead 4, a first flat diffusion space 421, a second flat diffusion space 422, and a third flat diffusion space 431 are stacked on each other with intervals therebetween, in this order from above. These diffusion spaces 421 to 431 are formed to have coaxial circular shapes. The third diffusion space 431 has a diameter larger than those of the first diffusion space 421 and the second diffusion space 422.

Arrangement of the respective introduction ports 51a to 54a in the upper surface of the gas showerhead 4 is described. As shown in FIG. 2, the first introduction port 51a is disposed in a central part of the upper surface of the gas showerhead 4 at one position. On the assumption that the Y direction shown in FIG. 2 is a front side, the second introduction ports 52a surrounding the first introduction port 51a are disposed at four positions, i.e., a front side position, a rear side position, a right side position, and a left side position. The third introduction ports 53a are formed at four positions which are outside these second introduction ports 52a. Thus, the nine introduction ports 51a to 53a in total are arranged in the central area of the upper surface of the gas showerhead 4 in a crossing manner. The fourth introduction ports 54a for a purge gas are diagonally disposed at two positions about the first introduction port 51a.

The first introduction port 51a is in communication with the first diffusion space 421 through a first gas introduction conduit 511. As described below, the gas showerhead 4 is structured by stacking four plates. The first gas introduction conduit 511 is formed vertically to the uppermost plate 41 of the plate group.

The second introduction ports 52a are in communication with the second diffusion space 422 through second gas introduction conduits 521. The third introduction ports 53a are in communication with the third diffusion space 431 through third gas introduction conduits 531. The second gas introduction conduits 521 extend vertically from the uppermost plate 41 through the second diffusion space 421. Thus, in the first diffusion space 421, there are arranged small cylindrical parts 423 whose inside spaces form the second gas introduction conduits 521. The third gas introduction conduits 531 extend from the uppermost plate 41 to the third diffusion space 431 such that positions of the third gas introduction conduits 531 in a planar direction are located outside the first diffusion space 421 and the second diffusion space 422.

Further, disposed between a bottom surface of the first diffusion space 421 and the gas supply surface 40a of a lower surface of the gas showerhead 4 are a number of vertical first gas supply conduits 512 whose upper and lower ends are opened to the bottom surface and the gas supply surface 40a. The first gas supply conduits 512 pass through the second diffusion space 422 and the third diffusion space 431. Thus, in parts of the diffusion spaces 422 and 431, through which the first gas supply conduits 512 pass, there are respectively arranged small cylindrical parts 425 and 432 whose inside spaces form the first gas supply conduits 512.

Furthermore, disposed between a bottom surface of the second diffusion space 422 and the gas supply surface 40a of the lower surface of the gas showerhead 4 are a number of vertical second gas supply conduits 522 whose upper and lower ends are opened to the bottom surface and the gas supply surface 40a. The second gas supply conduits 522 pass the third diffusion space 431. Thus, in parts of the third diffusion space 431, through which the second gas supply conduits 522 pass, there are arranged small cylindrical parts 433 whose inside spaces form the second gas supply conduits 522.

Still furthermore, disposed between a bottom surface of the third diffusion space 431 and the gas supply surface 40a of the lower surface of the gas showerhead 4 are a number of vertical third gas supply conduits 532 whose upper and lower ends are opened to the bottom surface and the gas supply surface 40a. Regarding the name of each gas conduit, the gas conduit extending from the introduction port to the diffusion space is referred to as “gas introduction conduit”, and the conduit extending from the diffusion space to the lower surface of the gas showerhead 4 is referred to as “gas supply duct”.

Since the central area of the gas showerhead 4 is as structured above, by respectively introducing the Sr material gas, the Ti material gas, and the ozone gas to the first introduction port 51a, the second introduction port 52a, and the third introduction port 53a, these gases pass through the conduits that are independent from each other, and then the gases are supplied from the gas supply surface 40a of the lower surface of the gas showerhead 4 to a central area 10a of the process atmosphere 10 shown in FIG. 1. By switching the gases to be supplied to the introduction ports 51a to 53a to a purge gas, the purge gas can be supplied to the central area 10a.

Next, a supply structure of the process gas in the peripheral area of the gas showerhead 4 is described. As described above, the two fourth introduction ports 54a are disposed in the area outside the central area in the upper surface of the gas showerhead 4 at the opposed positions with the center of the gas showerhead 4 being interposed therebetween. In the peripheral area, a ring-like fourth diffusion space 411 is formed at a position higher than the first diffusion space 421. In order to introduce a gas from the two fourth introduction ports 54a to the fourth diffusion space 411, fourth gas introduction conduits 541, which vertically extend, are formed. A ring-like fifth diffusion space 441 is formed in a lower projection area of the fourth diffusion space 411 at a position lower than the third diffusion space 431. Two fifth gas introduction conduits 542, which vertically extend, are formed to allow a gas to flow from the fourth diffusion space 411 to the fifth diffusion space 441.

The upper fourth gas introduction conduits 541 and the lower fifth gas introduction conduits 542 are alternately shifted by 90 degrees in the circumferential direction of the gas showerhead 4. Disposed between a bottom surface of the fifth diffusion space 441 and the gas supply surface 40b of the lower surface of the gas showerhead 4 are a number of vertical fourth gas supply conduits 543 whose upper and lower ends are opened to the bottom surface and the gas supply surface 40b.

Due to the structure of the peripheral area of the gas showerhead 4, by introducing the purge gas to the fourth introduction ports 54a, the purge gas can be supplied from the peripheral area 10b, which is outside the central area 10a for supplying the process gases, in the gas supply surface 40b of the lower surface of the gas showerhead 4.

As shown in FIG. 2, the gas showerhead 4 is structured by stacking the four plates (members). On the assumption that the uppermost plate is a first member, the first to third members are formed of plates 41, 42, and 43 whose planar shape is circular. A fourth member is composed of a circular plate 45 positioned on the central area, and a ring-like plate 44 positioned on the peripheral area so as to surround the plate 45.

The first plate 41 has a flange part 41a on an upper periphery thereof. As shown in FIG. 1, the flange part 41a is disposed between the first plate 41 and the inner block 26. The flange part 41a is sealingly in contact with an upper surface of the step of the ring support member 25. A lower part of the flange part 41a of the plate 41 and side peripheral surfaces of the second to fourth plates 42, 43, and 44 are sealingly in contact with the inner peripheral surfaces of the support member 25 and the baffle ring 27, so as to be fixed on the process container 2.

As shown in FIGS. 3 and 4, a ring-like groove is formed in a lower surface of the first plate 41. A space defined by the groove and an upper surface of the second plate 42 corresponds to the ring-like fourth diffusion space 411. The first gas introduction conduit 511 and the fourth gas introduction conduits 541 are formed in the first plate 41.

As shown in FIGS. 2 to 4, circular recesses whose planar shape is circular are formed in upper and lower surfaces of the central area of the second plate 42. A space defined by the upper recess and the first plate 41 corresponds to the first diffusion space 421, and a space defined by the lower recess and the third plate 43 corresponds to the second diffusion space 422.

As shown in FIGS. 3 and 4, a recess whose planar shape is circular is formed in a lower surface of the central area of the third plate 43. A space defined by the recess and an upper surface of the fourth circular plate 45 corresponds to the third diffusion space 431.

As shown in FIGS. 2 to 4, a ring-like recess is formed in an upper surface of the fourth ring-like plate 44 in a circumferential direction of the plate 44. A space defined by the recess and a lower surface of the third circular plate 43 corresponds to the fifth diffusion space 441. In FIG. 2, the reference numbers of the recesses show the corresponding diffusion spaces.

As shown in FIGS. 3 and 4, the aforementioned gas introduction conduits 521, 531, and 542 and the gas supply conduits 512 and 522 are formed in a divided manner in the plurality of corresponding plates of the first to fourth plates 41, 42, 43, 45, and 44. As described above, the parts of the diffusion spaces, through which the gas introduction conduits or the gas supply conduits pass, are structured as the cylindrical parts 423, 425, 432, and 433. Thus, the cylindrical parts 423, 425, 432, and 433 project downward from top surfaces of the recesses forming the diffusion spaces 421, 422, and 431 or project upward from bottom surfaces of the recesses.

In the diffusion spaces 422 and 431, owing to the existence of the plurality of cylindrical parts 425, 432, and 433, heat is transferred through these parts. However, since the number of cylindrical parts 423 in the diffusion space 421 is smaller, a columnar part 424 projecting upward from the bottom surface of the recess to the upper plate is disposed at a location other than the aforementioned cylindrical parts 423, in order that heat can be easily transferred between the upper and lower plates 41 and 42.

Upper end surfaces or lower end surfaces of the cylindrical parts 423, 425, 432, and 433 and the columnar part 424 are coplanar with (positioned at the same height) the surfaces of the plates 42 and 43 other than the recesses. Thus, the upper end surfaces of the lower end surfaces of the cylindrical parts 423, 425, 432, and 433 are sealingly in contact with the surfaces of the opposed plates 41, 43, and 45, whereby a gas flowing through the cylindrical parts 423, 425, 432, and 433 can be prevented from leaking into the gas diffusion spaces 421, 422, and 432. Hereabove, the aforementioned gas diffusion spaces 421, 422, 431, 411, and 441, the gas introduction conduits 511, 521, 531, 541, and 542, and the gas supply conduits 512, 522, 532, and 543, which are disposed in the respective plates 41 to 45, constitute a gas conduit structure part for independently supplying the first to third process gases (Sr material gas, Ti material gas, and ozone gas) to the process atmosphere.

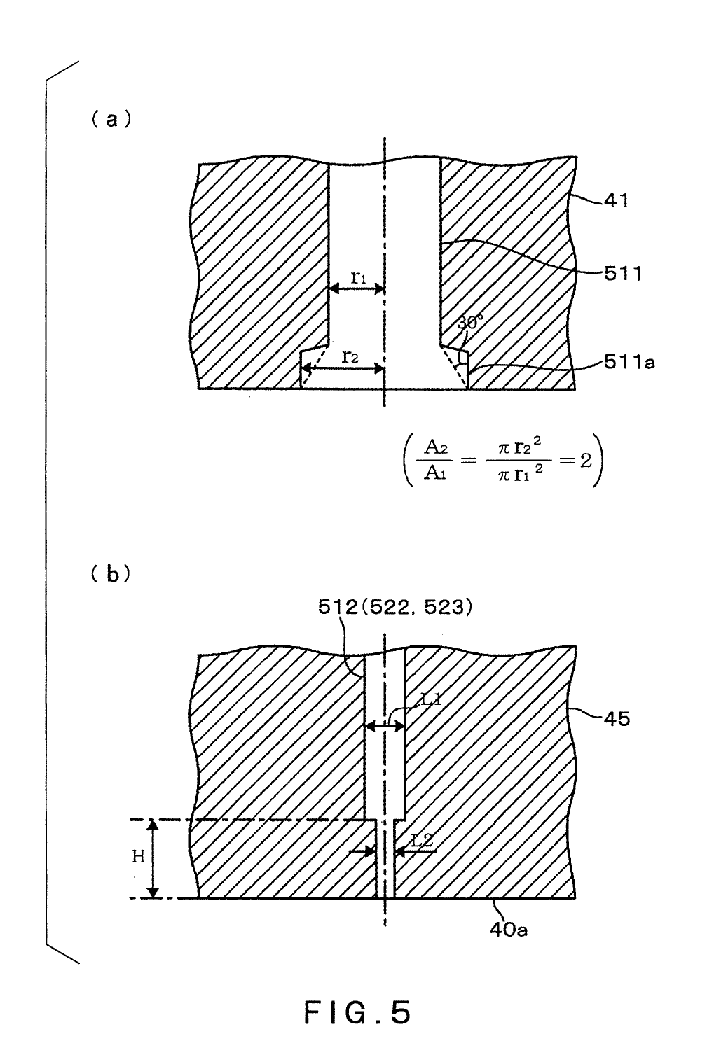

Larger diameter parts are formed at positions where the gas introduction conduits 511, 521, 541, and 542 are opened to the gas diffusion spaces 421, 422, 411, and 441. In detail, as shown in FIG. 5(a) showing the first gas introduction conduit 511 as a representative, for example, the first gas introduction conduit 511 and an opening part 511a thereof are cylindrically formed in the following manner. Namely, a cross-sectional area A₂ (=πr₂² wherein r₂ is a radius of the section) of the opening part 511a is about twice a cross-sectional area A₁ (=πr₁² wherein r₁ is a radius of the section) of the first gas introduction conduit 511. In addition, an angle between an imaginary surface (shown by the broken lines in FIG. 5(a)), which connects a distal end of the first gas introduction conduit 511 and a distal end of the opening part 511a, and a side peripheral surface of the opening part 511a, is 30°. Due to the provision of the larger diameter part, it is easy to diffuse a gas from the gas introduction conduit 511, 521, 541, and 542 into the gas diffusion spaces 421, 422, 411, and 441.

As shown in FIG. 5(b), each of the gas supply conduits 512, 522, and 532 formed in the fourth circular plate 45 has a lower part whose bore is smaller than that of an upper part thereof. For example, the bore L1 of the upper part is 2 mm, the bore L2 of the lower part is 1 mm, and a height H of the lower part is 5 mm. Owing to the smaller bores of the gas supply conduits 512, 522, and 532, Peclet numbers “Pe” of the supply conduits 512, 522, and 532 can be made larger, whereby the process gases or the like supplied into the process atmosphere 10 can be prevented from flowing into the diffusion spaces 421, 422, and 431. In this embodiment, a slight amount of the purge gas is flown from the gas supply conduits 512, 522, and 532 while no process gas is supplied. The bores of the lower parts are set such that a Peclet number when the purge gas flows therethrough is not less than 20 (Pe≧20). Herein, Pe=Vs·H/D in which Vs represents a flow velocity of the purge gas flowing through the lower parts of the gas supply conduits 512, 522, and 532, and D represents a diffusion constant of the material gas.

Bolt holes 81a to 84a and 81b to 84b are drilled in the respective plates 41 to 45 of the gas showerhead 4 such that the plates 41 to 45 are fastened to each other. FIGS. 3 and 4 show some of the bolt holes as representatives. As shown in FIG. 2, the gas showerhead 4 shown in FIGS. 3 and 4 is structured by using these bolt holes 81a to 84a and 81b to 84b, for example. Namely, the plate 41 and the plate 42 are firstly fastened by a bolt 81, and then the center of the plate 43 and the center of the plate 45 are fastened by a bolt 82. Thereafter, the plate 43 is fastened to the lower surface of the plate 42 by a bolt 83, and finally the plate 44 is fastened to the lower surface of the plate 43. For convenience of illustration, the above bolts 81 to 84 are shown by way of example as the bolts fastening the respective members 41 to 45. Actually, the respective members 41 to 45 are securely fastened to each other by means of a number of bolts. For convenience of illustration, illustration of the bolt holes 81a to 84a and 81b to 84b are omitted in FIGS. 3 and 4.

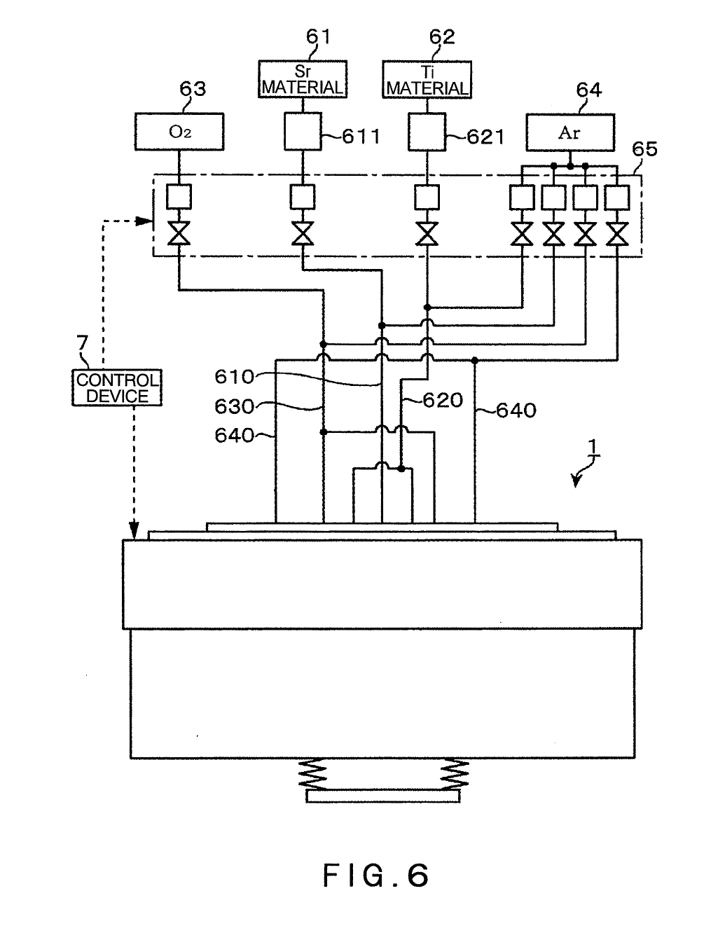

As shown in FIG. 4, gas supply lines 610 to 640 through which the respective gases are supplied are connected to the respective introduction ports 51a to 54a in the upper surface of the uppermost plate 41. That is to say, the first introduction port 51a is connected to the Sr-material gas supply line 610, the second introduction ports 52a are connected to the Ti-material gas supply line 620, the third introduction ports 53a are supplied to the ozone-gas supply line 630, and the fourth introduction ports 54a are connected to the purge-gas supply line 640. As shown in FIG. 6 showing gas supply paths, the respective gas supply lines 610 to 640 are connected to respective supply sources 61 to 64 on n upstream side.

In detail, the Sr-material supply line 610 is connected to the Sr-material supply source 61 that stores a liquid Sr material such as Sr(THD)₂ (strontium bistetra methyl heptanedionato) and Sr(Me₅ Cp)₂ (bis pentamethyl cyclopenta dienyl strontium). The Sr material is extruded to the supply conduit, and is evaporated by an evaporator 611. Then, the evaporated Sr material is supplied to the Sr-material supply line 610.

The Ti-material supply line 620 is connected to the Ti-material supply source 62 that stores a Ti material such as Ti(OiPr)₂(THD)₂ (titanium bis-isopropoxide bistetra methyl heptanedionato) and Ti(OiPr) (titanium tetra isopropoxide). Similarly to the Sr material, the Ti material is extruded to the supply conduit, and is evaporated by an evaporator 621. Then, the evaporated Ti material is supplied to the Ti-material supply line 620.

The ozone-gas supply line 630 is connected to the ozone-gas supply source 63 formed of, e.g., a well-known ozonizer. The purge-gas supply line 640 is connected to the purge-gas supply source 64 formed of an argon-gas cylinder. Thus, an ozone gas and an argon gas can be supplied to the respective supply lines 630 and 640. The respective Sr-gas supply line 610, the Ti-material supply line 620, and the ozone-gas supply line 630 are branched, and the respective branched conduits are connected to the purge-gas supply source 64. Thus, a purge gas, instead of the respective process gases, can be supplied from the respective gas supply lines 610 to 630. In addition, disposed between the gas supply lines 610 to 640 and the gas supply sources 61 to 64 is a flow-rate controller group 65 composed of valves and flowmeters. Thus, based on a command from a control device 7, which will be described below, supply rates of the respective gases can be controlled. Although the respective gas supply lines 610 to 640 are connected to all the eleven introduction ports 51a to 52 shown in FIG. 2, illustration of some of the introduction ports 51a to 54 are omitted in FIGS. 1 and 6 as a matter of convenience.

Returning to the description of the apparatus structure of the film deposition apparatus 1, as shown in FIG. 1, the upper surface of the gas showerhead 4, and the lower surface and the upper surface of the outer wall surface of the exhaust duct 21 are provided with a showerhead heater 47 formed of a sheet-like heating resistor and a duct heater 213. By heating the entire gas showerhead 4 and the entire exhaust duct 21 by means of an electric power supplied from the power source 68, the adhesion of the reactants to the gas supply surface 40 of the gas showerhead 4 and the inner surface of the exhaust duct 21 can be prevented. For convenience of illustration, illustration of heaters 47 and 213 is omitted excluding FIG. 1. In addition to the above heaters, a heater for preventing the adhesion of the reactants is embedded in the inner block 26, for example. However, illustration thereof is omitted as a matter of convenience.

The film deposition apparatus 1 as described above is equipped with the control device 7 that controls a gas supply operation from the aforementioned gas supply sources 61 to 63, a vertical movement of the stage 31, an exhaust operation in the process container 2 by the vacuum pump 67, and a heating operations of the respective heaters 47 and 213. The control device 7 is formed of a computer, not shown, including a CPU and a program. The program has a step (command) group required for the film deposition apparatus 1 to control the respective members so as to perform a film deposition process to a wafer W, for example, to perform a control of gas supply and stop timings and supply rates of the respective gases from the gas supply sources 61 to 64, an adjustment of a vacuum degree in the process container 2, control of a vertical movement of the stage 31, and a control of temperatures of the respective heaters 47 and 213. Such a program is stored in a storage medium such as a hard disc, a compact disc, a magnetoptical disc, and a memory card, and is generally installed on the control device 7 from the storage medium.

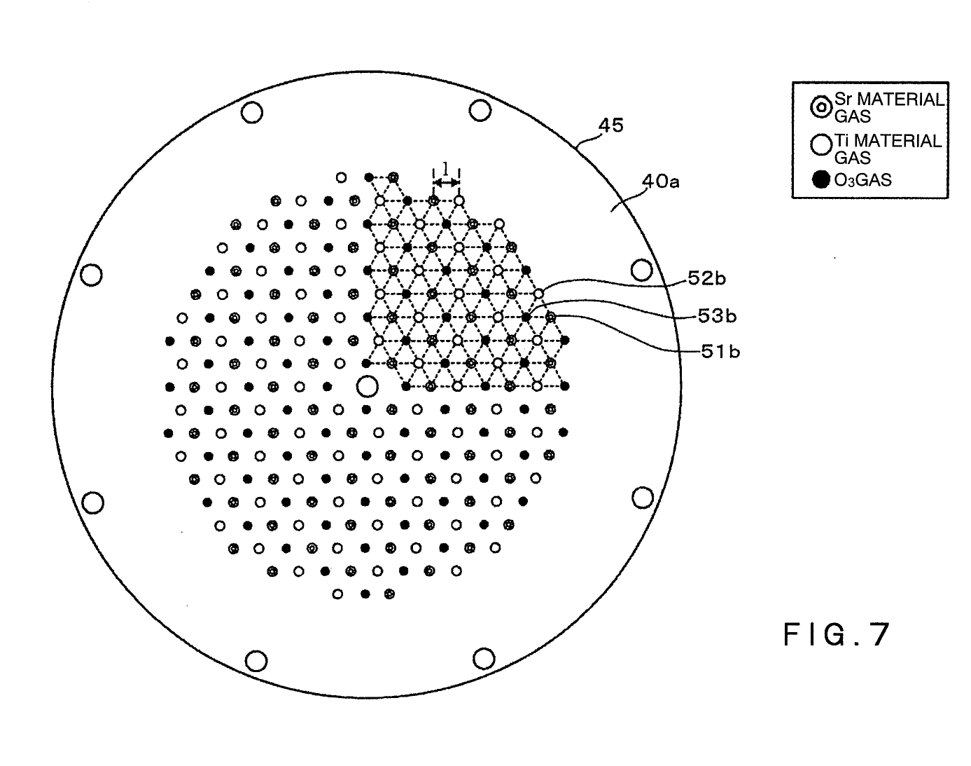

In the film deposition apparatus 1 having the above-described apparatus structure, the arrangement of the gas supply holes for the respective gases formed in the gas supply surface 40a of the gas showerhead in this embodiment is determined such that, when an STO film is deposited with the use of the three kinds of gases, i.e., the Sr material gas, the Ti material gas, and the ozone gas, an excellent in-plane uniformity of a film thickness and of a film quality of the STO film can be achieved. Herebelow, details of the arrangement is described with reference to FIGS. 7 to 11.

FIG. 7 is a plan view of the fourth circular plate 45 shown in FIG. 2, which is viewed from a lower surface side thereof. There is shown the arrangement of the gas supply holes 51b to 53b for the respective gases in the central area of the gas supply surface 40a of the gas showerhead 4. For a matter of convenience, the respective gas supply holes 51b to 53b shown in FIGS. 7, 10, and 11 are shown by different symbols for identification. Namely, in the gas supply surface 40a, the Sr-material gas supply hole 51b for supplying the Sr material gas is shown by “⊚”, the Ti-material gas supply hole 52b for supplying the Ti material gas is shown by “◯”, and the ozone-gas supply hole 53b for supplying the ozone gas is shown by “”.

As in this embodiment, in the gas showerhead 4 that deposits a film by supplying a process gas to a wafer W opposed thereto from the plurality of gas supply holes 51b to 53b formed in the gas supply surfaces 40a, intervals (hereinafter referred to as “pitches”) between the gas supply holes 51b to 53b, and a distance (hereinafter referred to as “gap”) between the surface of the wafer W placed on the table 3 and the gas supply surface 40a of the gas showerhead 4, exert an effect on an in-plane uniformity of a film quality and of a film thickness.

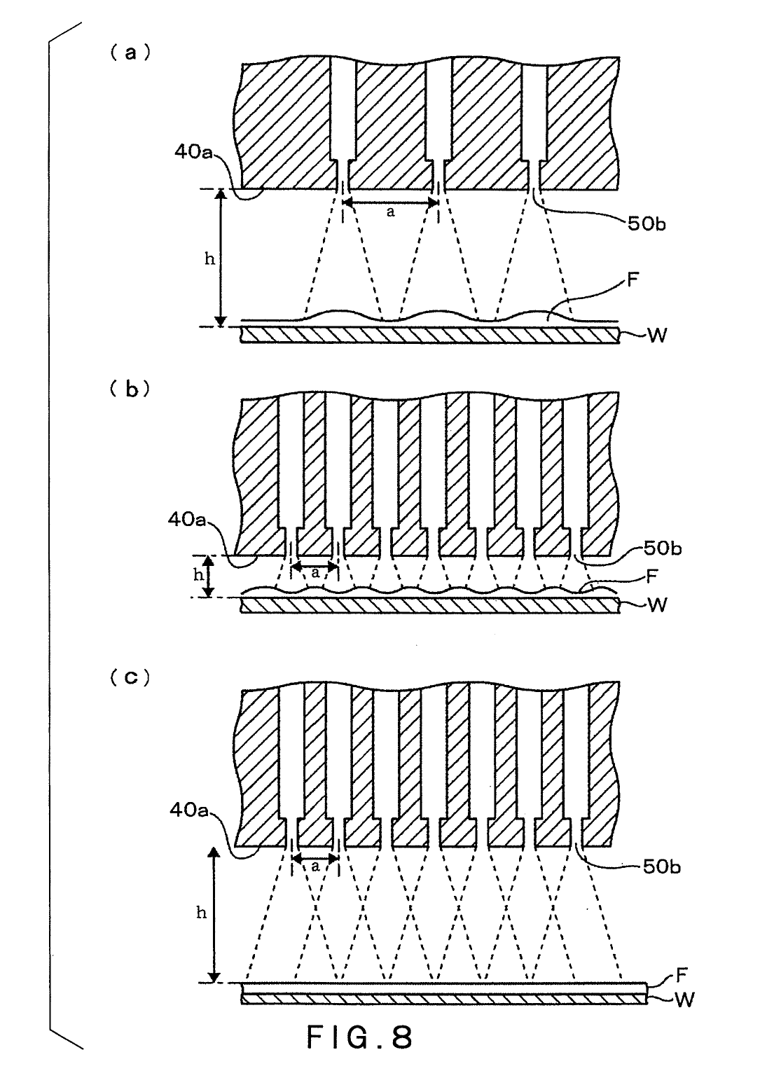

Namely, as shown in FIG. 8(a) schematically showing a pitch a between the gas supply holes 50b for supplying a certain kind of gas, and a gap h between the gas supply surface 40a and the surface of the wafer W, when the pitch between the gas supply holes 50b is large, the process gas supplied from the respective gas supply holes 50b reaches the wafer W, before the process gas supplied from the certain gas supply hole 50b sufficiently diffuses so as to form, together with the process gas supplied from the gas supply hole 50b adjacent to the certain gas supply hole 50, a uniform process gas atmosphere. As a result, there are formed, in the surface of the wafer W, areas in which a large amount of the process gas is adsorbed and areas in which a small amount of the process gas is adsorbed, which invites a phenomenon (referred to as “transfer of the gas supply holes 50b”) in which a thickness of a film F becomes thicker at positions near to the gas supply holes 50b in accordance with the arrangement pattern of the gas supply holes 50b. Alternatively, even when the pitch between the gas supply holes 50b is made smaller but the gap between the gas supply surface 40a and the wafer W is small, a flow velocity of the gas to be jetted is too fast to invite a phenomenon in which the thickness of the film F becomes thinner at positions near to the gas supply holes 50b, resulting in the transfer of the gas supply holes 50b as shown in FIG. 8(b).

The transfer of the gas supply holes 50b occurs as the value of the pitch a increases (in proportion to the value of the pitch a). In addition, the transfer of the gas supply holes 50b occurs when the value of the gap h is too large and too small. Thus, in order to obtain a film F having a uniform film thickness without transfer, it is preferable to perform a film deposition process under conditions where the pitch a is sufficiently small with the suitable gap h, which is shown in FIG. 8(c), for example. For the matter of convenience, in the respective FIGS. 8(a) to 8(c), only the gas supply holes 50b for supplying the certain kind of gas, which have been described above, are illustrated, and illustration of the gas supply holes of other kinds is omitted.

As described above with reference to FIG. 1, in the actual film deposition apparatus 1, the process container 2 is always exhausted by the vacuum pump 67, whereby flows of the process gases are formed between the gas supply surface 40a and the wafer W by the evacuation operation. Thus, behaviors of the process gas supplied from the gas supply holes 50b are more complicated than the illustration models shown in FIGS. 8(a) to 8(b). However, based on the aforementioned mechanism, a degree of the transfer of the gas supply holes 50b to the film F is greatly affected by the pitch between the gas supply holes 50b and the gap between the gas supply surface 40a and the wafer W.

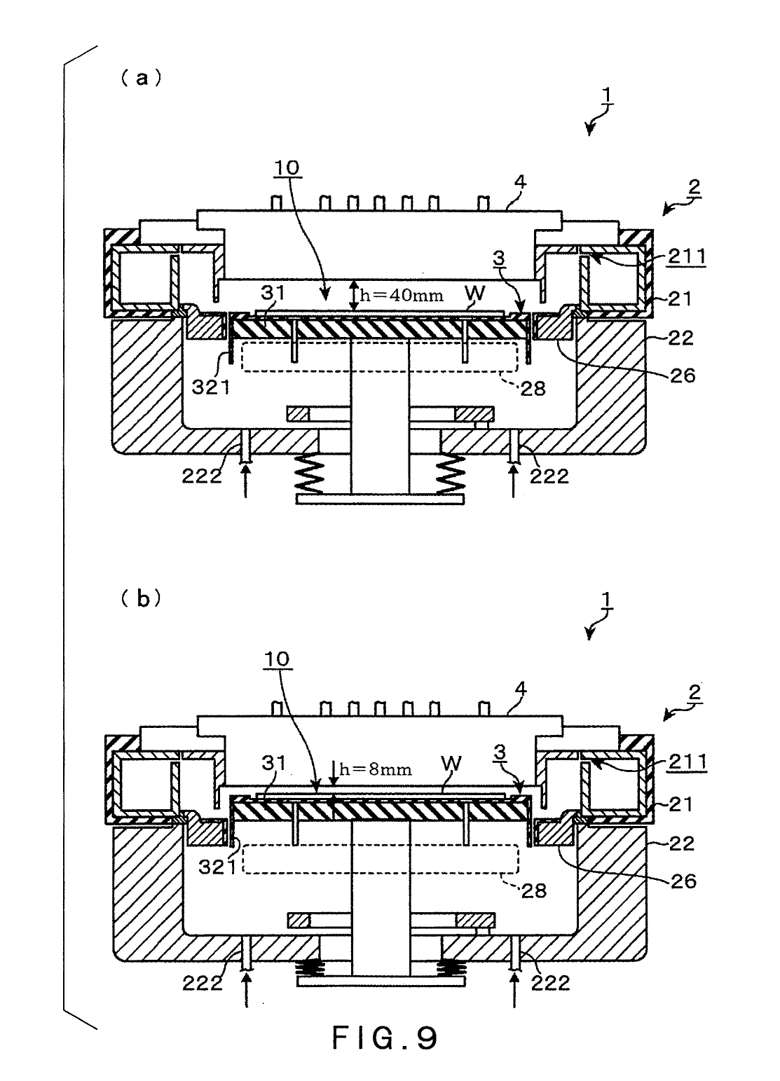

In the film deposition apparatus 1 in this embodiment, as has been described with reference to FIG. 1, the table 3 can be elevated and lowered between the transport position of the wafer W and the process position for the wafer W. The process position can be vertically, freely varied between the position at which the gap h is maximum, i.e., 40 mm, which is shown in FIG. 9(a), and the position at which the gap h is minimum, i.e., 8 mm, which is shown in FIG. 9(b). The process position is determined by a method that selects the optimum process position, which has been stored beforehand, in accordance with recipes specifying film deposition conditions, for example. From the viewpoint of restraining amounts of the respective gases to be used, it is generally required that a film deposition process is performed at a process position where the gap is as short as possible. Thus, in the gas showerhead 4, it is necessary to arrange the respective gas supply holes 51b to 53b in the gas supply surface 40a at pitches that can avoid the transfer, even when the process is performed at a position where the gap h is minimum.

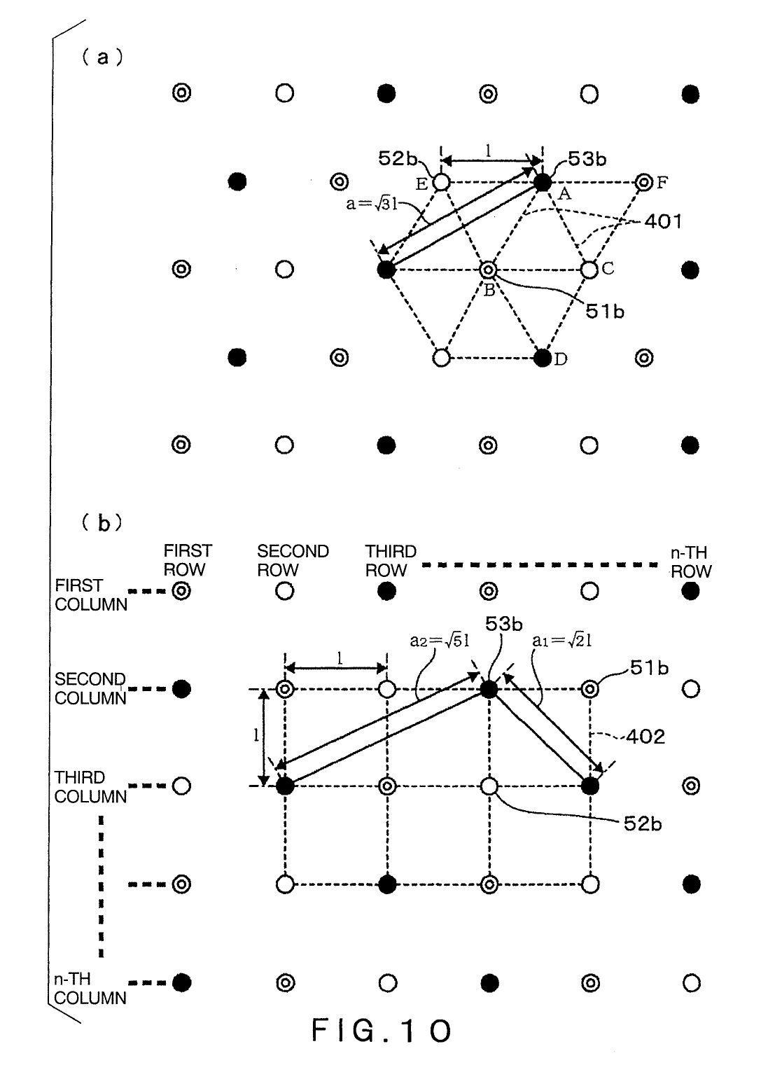

From this point of view, as shown in FIGS. 7 and 10(a), the gas supply surface 40a of the gas showerhead 4 in this embodiment is divided into unit zones 401 formed of regular triangles of the same size. The first gas supply hole 51b, the second gas supply hole 52b, and the third gas supply hole 53b are allocated to respective three apexes of each regular triangles forming the unit zone 401.

Namely, in the arrangement technique shown in FIG. 10(a), the ozone-gas supply hole 53b is allocated to, e.g., an apex A of a triangle ABC, the Sr-material gas supply hole 51b is allocated to, e.g., an apex B thereof, and the Ti-material gas supply hole 52b is allocated to, e.g., an apex C thereof. Thereafter, there is drawn another triangle BCD that is axisymmetric (line-symmetric) with the triangle ABC with respect to an edge (side) BC thereof. Then, another ozone-gas supply hole 53b, which is axisymmetric with the ozone-gas supply hole 53b allocated to the apex A, is allocated to an apex D. Similarly, there are drawn other triangles that are axisymmetric with the triangle ABC with respect to edges AB and AC thereof, and another Ti-material gas supply hole 52b is allocated to an apex E, and another Sr-material gas supply hole 51b is allocated to an apex F. By repeating this operation, the gas supply holes for the respective gases are formed in the gas supply surface 40a of the gas showerhead 4. According to this manner, there necessarily exist the three gas holes respectively for the three kinds of gases in each unit zone 401. That is to say, distribution densities of the three kinds of gas holes are equal to each other. In addition, distances between the adjacent gas holes for the respective gases are equal to each other (as described below, the distance is \sqrt{3}l for all the three kinds of gas holes), whereby all the gases can be uniformly jetted to the process atmosphere 10a.

As shown in FIG. 5(b), when the bore L1 of the upper part of each of the gas supply conduits 512, 522, and 532 is 2 mm, a machining limit between the adjacent gas conduits 512, 522, and 532 is for example, about 7 mm, from the aspect of a fabrication precision and a thicknesses of walls required between the adjacent gas conduits 512, 522, and 532. In this case, as shown in FIG. 10(a), since the length l of each edge of the unit zone 401 is 7 mm, the pitch a between the ozone-gas supply holes 53b is (\sqrt{3})l, i.e., about 12 mm. The pitch between the gas supply holes 51b and the pitch between the gas supply holes 52b can be calculated in the same manner.

Another arrangement technique shown in FIG. 10(b) as a comparative example is examined with respect to the above arrangement technique. In this comparative arrangement technique, the gas supply surface 40a is divided like a grid into unit zones 402 formed of regular tetragons of the same size, for example. The gas supply holes 51b to 53b are allocated to the grid points in a column (in a lateral direction) in the order of 51b, 52b, and 53b. These columns are arranged such that positions of each of the gas supply holes 51b to 53b in the first column are shifted to rightward positions in the second column. In this manner, the n-th column and the (n+1)-th column have the same relationship.

Similarly to the arrangement in this embodiment shown in FIG. 10(a), when a length l of each edge of the unit zone 402 is 7 mm, there exist two kinds of pitches between the ozone-gas supply holes 53b, for example. Namely, one pitch a₁ is (\sqrt{2})l, i.e., about 9.9 mm which is smaller than the pitch of the arrangement in this embodiment shown in FIG. 10(a), while the other pitch a₂ is (\sqrt{5})l, i.e., about 15.7 mm which is larger than the pitch of the arrangement in this embodiment.

When a film deposition is performed by using a gas showerhead having the gas supply surface 40a in which the smaller pitches a₁ and the larger pitches a₂ exist in a mixed manner, as in the above-described arrangement technique, there exist areas whose degree of transfer of the gas supply holes 51b to 53b to the deposited film is large, and areas whose degree of the transfer is small, in a mixed manner. However, in general, a uniformity of a film thickness is evaluated with the use of a maximum value of a difference between an average value of the film thickness and the actual film thickness. Thus, the evaluation of the uniformity of the film thickness of the overall film is performed in the area whose degree of transfer is large. Thus, as compared with the arrangement technique shown in FIG. 10(a), the uniformity of the film thickness of the overall film is degraded.

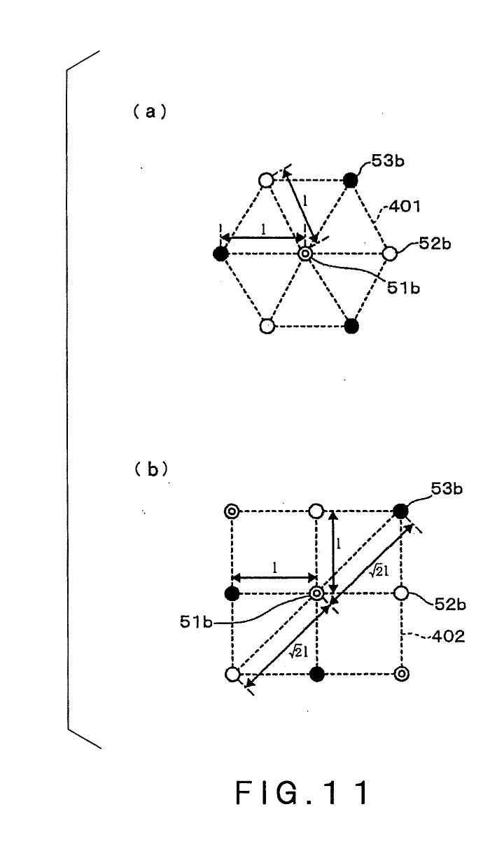

The arrangement techniques shown in FIGS. 10(a) and 10(b) are compared to each other, in terms of film quality. For example, STO is a compound in which strontium atoms, titanium atoms, and oxygen atoms are combined at a ratio of 1:1:3. Such a ratio is adjusted by densities (concentrations) of the gases supplied from the respective material supply sources 61 to 63, for example. In order to examine the influence of the arrangement technique in this embodiment shown in FIG. 10(a) on a gas adsorption to a wafer W, there is studied the six unit zones 401, as shown in FIG. 11(a), which surround the certain Sr-material gas supply hole 51b. At this time, when viewed from an area of the wafer W which is positioned directly below the Sr-material gas supply hole 51b, the process gases to be supplied from the Ti-material gas supply holes 52b and the ozone-gas supply holes 53b are supplied from the gas supply holes 52b and 53b which are distant from the central Sr-material gas supply hole 51b by the same distance l. Thus, the timings at which the gases reach the area of the wafer W and the adsorption periods are the same, whereby it is considered that a gas adsorption density in this area of the wafer W becomes uniform.

On the other hand, the influence of the other arrangement technique is similarly examined for the four unit zones 402 surrounding the certain Sr-material gas supply hole 51b. For example, the two ozone-gas supply hole 53b, i.e., the left and below ozone-gas supply holes 53b with respect to the central Sr-material gas supply hole 51b are distant therefrom by the distance l, while the upper right ozone-gas supply hole 53b with respect to the central Sr-material gas supply hole 51b is distant therefrom by the distance (\sqrt{2}l). Namely, the distances from the Sr-material gas supply hole 51b differ from each other. Thus, in the area of the wafer W positioned below the Sr-material gas supply hole 51, the timings at which the gas supplied from these supply holes 53b reaches the area of the wafer W and the adsorption periods differ from each other in the upper right part and the left below part of the area. For example, there is a possibility that a gas adsorption density might be non-uniform, i.e., the gas adsorption density might be low in the upper right part of the area, while the gas adsorption density might be high in the lower left part. Meanwhile, regarding the three Ti-material gas supply holes 52b surrounding the central Sr-material gas supply hole 51b, since the arrangement state thereof is a state that is obtained by rotating the arrangement state of the ozone-gas supply holes 53b by 180°. Thus, there is a possibility that the gas adsorption density might be non-uniform, i.e., the gas adsorption density might be low in the lower left part of the area, while the gas adsorption density might be high in the upper right part.

When the adsorption amounts of the three kinds of gases become larger and smaller because of the non-uniform arrangement state, it is impossible to combine strontium atoms, titanium atoms, and oxygen atoms at a ratio of 1:1:3. In this case, there is a possibility that strontium oxide (SrO) and titanium oxide (TiO₂) might be mixed in the STO film, whereby an STO film having a uniform film quality cannot be obtained.

According to the aforementioned arrangement technique of the gas holes shown in FIG. 10(a), there can be manufactured a showerhead for four kinds of gases, in which distribution densities of the four kinds of gas holes are equal to each other, as well as distances between the gas holes for each kind of gas are equal to each other, by allocating the gas holes for the four kinds of gases to apexes of a regular tetragon, drawing other regular tetragons that are axisymmetric with the respective edges of the first regular tetragon, and allocating the gas holes for the four kinds of gases to apexes of the regular tetragons. This arrangement technique can be applied to other regular polygons (regular pentagon, regular hexagon, and so on). As compared with the arrangement technique shown in FIG. 10(b) as the comparative example, the arrangement technique shown in FIG. 10(a) is considered to be capable of achieving a higher in-plane uniformity of a film thickness and of a film quality. In the gas showerhead 4 in this embodiment, the arrangement technique of the three kinds of gas supply holes 51b to 53b is employed based on this theory. Herebelow, an operation of the film deposition apparatus 1 using such a gas showerhead 4 is described.

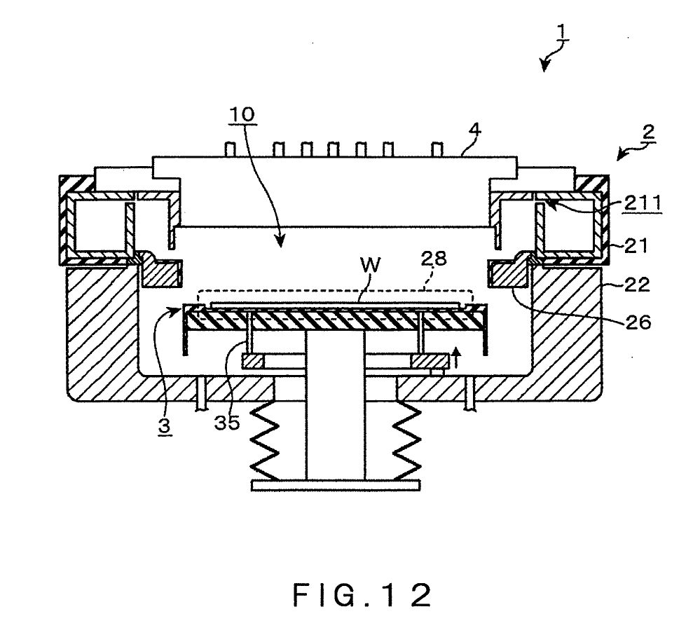

As shown in FIG. 12, the transport opening 28 is firstly opened, and a wafer W is loaded into the process container 2 by the external transport mechanism having entered from the transport opening 28. The, the wafer W is placed on the table 3 located at the transport position via the elevating pins 35, and the wafer W is absorbed by the electrostatic chuck, not shown (placing step). At this time, the surfaces of the exhaust duct 21 and the inner block 26 are respectively heated by the respective heaters 213 and 47 at a temperature of, e.g., 230° C., and the gas supply surface 40 of the gas showerhead 4 is heated at, e.g., 250° C. Then, the transport opening 28 is closed so that the process container 2 is hermetically sealed, the process container 2 is vacuumized by the vacuum pump 67 through the exhaust duct 21.

At this time, as described above, the inner block 26 is fixed at the position higher than the transport position for the wafer W. Thus, as shown in FIG. 12, in a state where the table 3 is lowered and located at the transport position for the wafer W, the space in the lower container 22 is in communication with the process atmosphere 10 (the space in the lower container 22 is not separated from the process atmosphere 10). Thus, in the aforementioned vacuum evacuation step, the inside space of the entire process container 2 including the inside space of the lower container 22 is evacuated to create a vacuum.

After the pressure in the process container 2 is reduced to a predetermined value, the table 3 on which the wafer W has been placed is elevated to the process position which selected in accordance with the recipes, i.e., to the process position at which the gap h is 8 mm, while the vacuum evacuation is continued. As shown in FIGS. 9(a) and 9(b), for example, when the table 3 is elevated to the process position, the side peripheral surface of the stage cover 32 or the skirt part 321 extending from the side peripheral surface is surrounded by the inner block 26, so that the process atmosphere located above the table 3 and the space inside the lower container 22 are separated from each other by the table 3 and the inner block 26 serving as blocks.

After the process atmosphere 10 and the space inside the lower container 22 have been separated from each other, there is started introduction of the purge gas into the lower container 22 through the purge-gas supply conduits 222. Then, a temperature of the wafer W is heated to, e.g., 280° C. by the stage heater 33. Thereafter, an STO film deposition process is started. In FIGS. 9(a), 9(b), and 12, illustration of the stage heater 33 is omitted as a matter of convenience. In the following description, the process position for the wafer W is assumed to be the position at which the gap h is 8 mm, which is shown in FIG. 9(b).

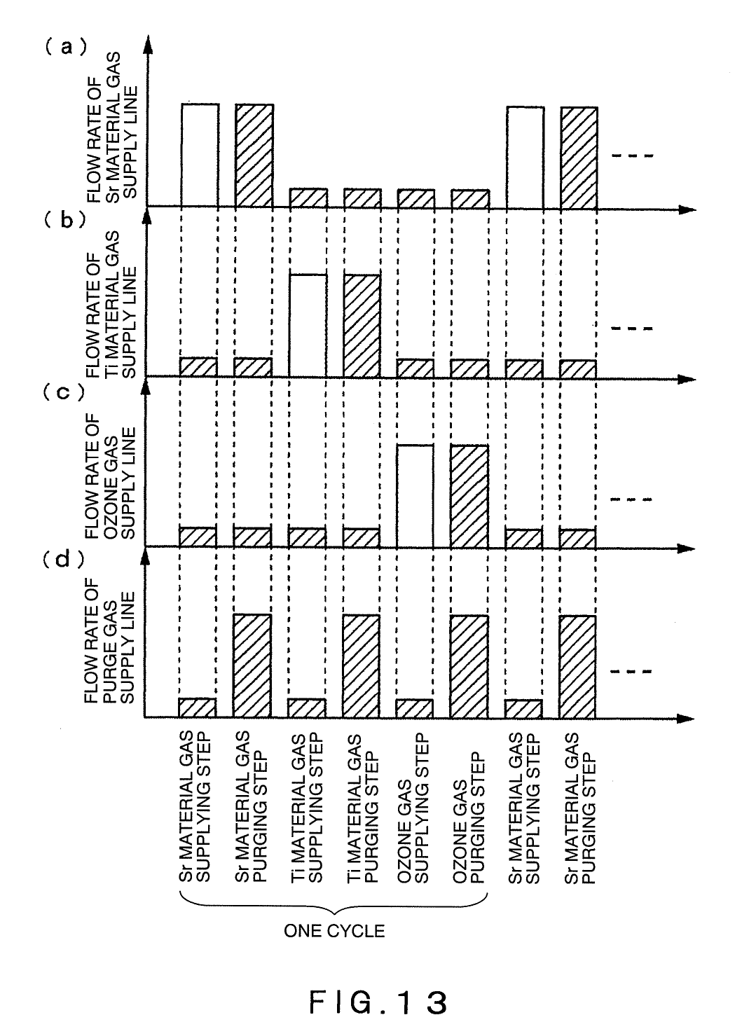

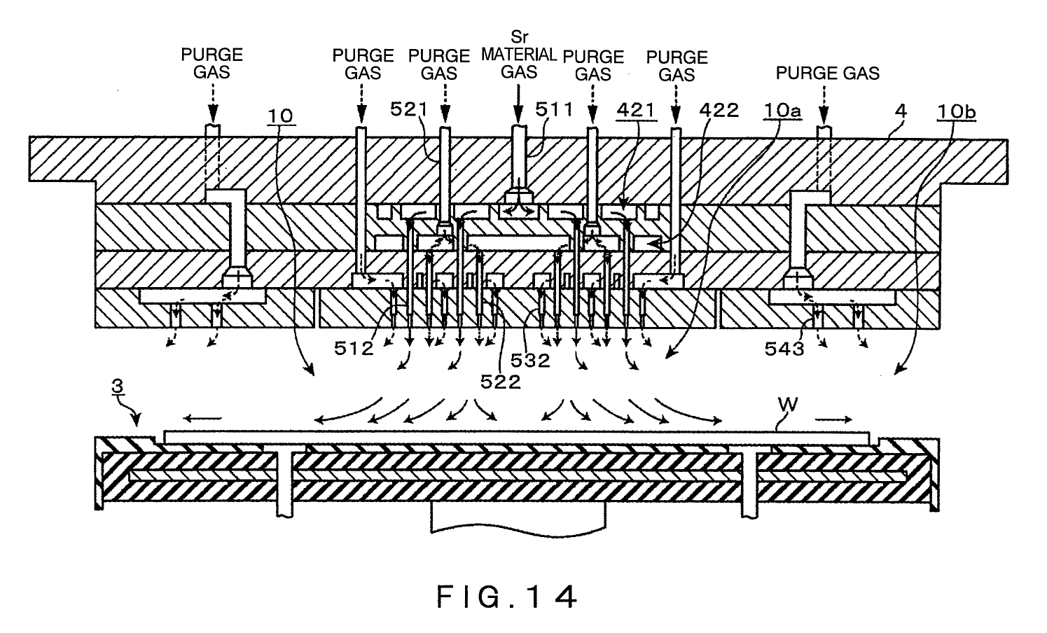

The STO film deposition process by the ALD method is performed based on a gas supply sequence shown in FIGS. 13(a) to 13(d). Unpatterned columns shown in (a) to (c) of FIGS. 13 (a) to 13(d) show flow rates of the process gases (Sr material gas, Ti material gas, and ozone gas) flowing through the respective gas supply lines 610 to 630. Meanwhile, hatched columns shown in FIGS. 13a (a) to 13(d) show supply rates of the purge gas flowing through the respective gas supply lines 610 to 640. FIGS. 14 to 17 schematically show the respective gas flows in the gas showerhead 4 and the process atmosphere 10 during the performance of the sequence.

As shown in FIG. 13(a), according to the gas supply sequence, supply of the Sr material gas is performed at first (Sr-material gas supplying step). At this time, in the gas showerhead 4, as shown in FIG. 14, the Sr material gas passes through the first gas introduction conduit 511 and diffuses in the first diffusion space 421. Then, the gas is supplied from the respective Sr-material gas supply holes 51b (see, FIG. 7) in the gas supply surface 40a to the central area 10a of the process atmosphere 10 through the plurality of first gas supply conduits 512 formed in the bottom surface of the first diffusion space 421.

In this manner, the Sr material gas is supplied from the central area of the gas supply surface 40a of the gas showerhead 4 to the process atmosphere 10 and reaches the central part of the wafer W placed on the table 3. At this time, as shown in FIG. 1, since the vacuum exhaust ports 211 disposed in the exhaust duct 21 are positioned such that the vacuum exhaust ports 211 surround the process atmosphere, the material gas having reached the central part of the wafer W flows from the central part of the wafer W to the peripheral part thereof toward the vacuum exhaust ports 211. Due to the gas flow from the central part of the wafer W to the peripheral part thereof, a moving distance of the material gas becomes shorter, so that molecules of the material gas can be adsorbed by the wafer W uniformly in the radial direction thereof.

As shown in FIGS. 13(b) to 13(d) and FIG. 14, a slight amount of purge gas is supplied from second gas supply conduits 522, the third gas supply conduits 532, and the fourth gas introduction conduit 541, in order to prevent a backflow of the material gas. On the other hand, the purge gas, which is supplied from the purge-gas supply conduits 222 of the lower container 22 shown in FIG. 1, enters the process atmosphere 10 through the clearance between the table 3 and the inner block 26, so as to restrain the material gas from flowing into the space inside the lower container 22 and prevent formation of deposits caused by the adhesion of the reactants. The supply of the purge gas from the clearance between the table 3 and the inner block 26 is continuously performed throughout the performance of the gas supply sequence.

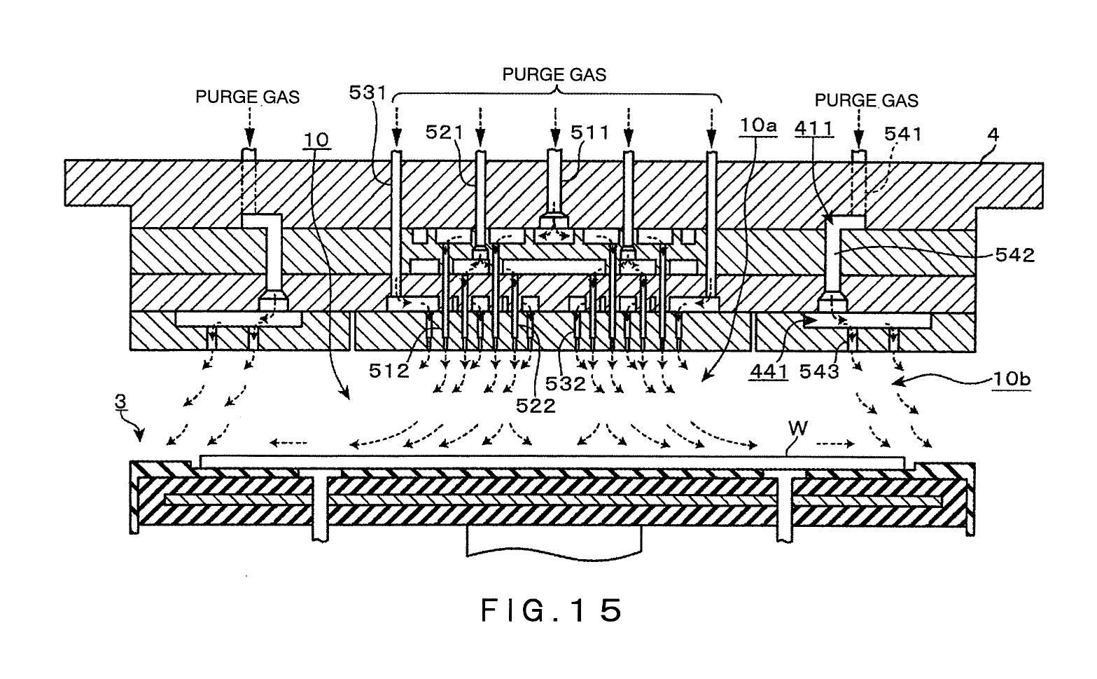

After a predetermined time has passed and the adsorption layer of the material gases has been formed on the wafer W, the supply of the material gases is stopped. As shown in FIGS. 13(a) to 13(d), the purge gas is supplied from the Sr-material gas supply line 610 and the purge-gas supply line 640, so that the Sr material gas remaining in the process atmosphere and in the gas showerhead 4 is purged (Sr-material gas purging step). At this time, in the gas showerhead 4, as shown in FIG. 15, the purge gas supplied from the Sr-material gas supply line 610 is supplied to the central area 10a of the process atmosphere 10 along the same path as that of the aforementioned Sr material gas. On the other hand, the purge gas supplied form the purge-gas supply line 640 passes through the fourth gas introduction conduits 541, the fourth diffusion space 411, the fifth gas introduction conduits 542 to reach the ring-like fifth diffusion space 441. Then, the purge gas is supplied to the peripheral area 10b of the process atmosphere 10 through the plurality of fourth gas supply conduits 543 formed in the bottom surface of the fifth diffusion space 441.

Since the purge gas is simultaneously supplied to both the central area 10a and the peripheral area 10b of the process atmosphere 10 in the process container 2, a larger amount of the purge gas is supplied as compared with a case in which the purge gas is supplied from only one of these areas. Thus, the material gas can be purged for a shorter time. At this time, as shown in FIGS. 13(b), 13(c), and 15, a slight amount of the purge gas is flown from the second gas supply conduits 522 and the third gas supply conduits 532.

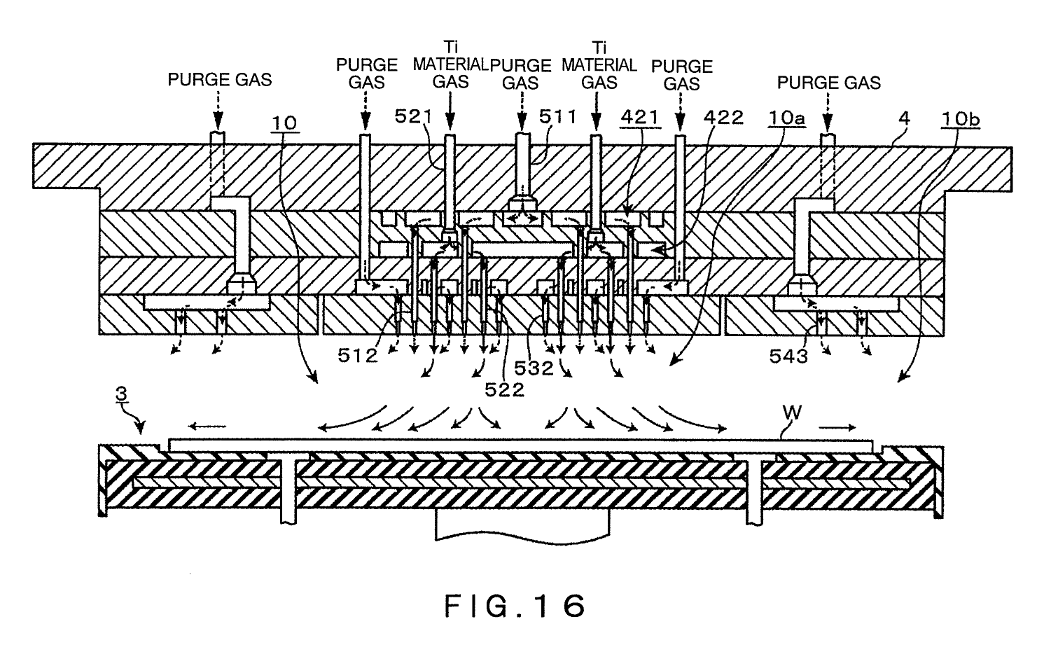

After the purge of the Sr material gas from the process atmosphere 10 is finished, as shown in FIG. 13(b), the Ti material gas is supplied. As shown in FIG. 16 the Ti material gas is supplied from the respective Ti-material gas supply holes 52b (see, FIG. 7) in the gas supply surface 40a to the central area 10a of the process atmosphere 10 through the second gas introduction conduits 521, the second diffusion space 422, and the third gas supply conduits 532 (Ti-material gas supplying step). Similarly to the Sr material gas, the Ti material gas flows from the central part of the wafer W to the peripheral part thereof, so that molecules of the Ti-material gas are adsorbed by the wafer W uniformly in the radial direction thereof. As shown in FIGS. 13(a), 13(c), 13(d) and FIG. 16, a slight amount of the purge gas is supplied from first gas supply conduit 512, the third gas supply conduits 532, and the fourth gas introduction conduit 541, in order to prevent a backflow of the material gas.

Then, as shown in FIG. 15, the Ti material gas is purged from the inside of the gas showerhead 4 and the process atmosphere 10 by the purge gas (Ti-material gas purging step). The Ti-material gas purging step differs from the above-described Sr-material gas purging step in the following point. Namely, in the Ti-material gas purging step, as shown in FIGS. 13(b) and 13(d), the purge gas is supplied form the Ti-material gas supply line 620 and the purge-gas supply line 640, which is a main operation. At the same time, as shown in FIGS. 13(a) and 13(c), a slight amount of the purge gas is supplied from the Sr-material gas line 610a and the ozone-gas supply line 630 to the respective first gas supply conduits 512 and the third gas supply conduits 532, in order to prevent a backflow of the material gas.

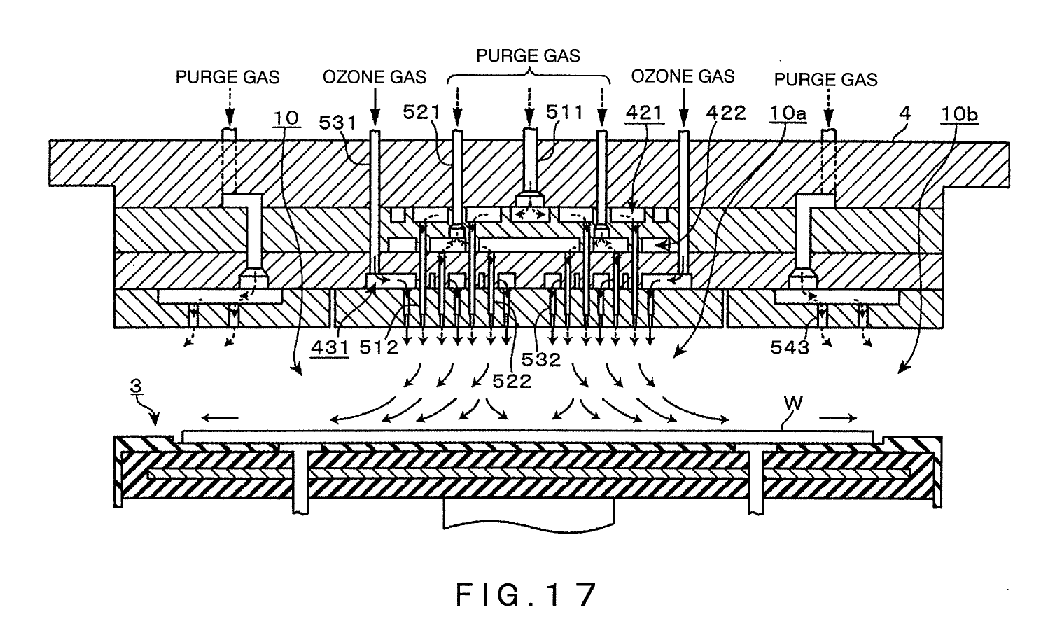

After the supplying steps and the purging steps of the Sr material gas and the Ti material gas, as shown in FIG. 13(c), supply of the ozone gas from the ozone-gas supply line 630 is performed (ozone-gas supplying step). As shown in FIG. 17, the ozone gas passes through the third gas introduction conduits 531 of the gas showerhead 4 and diffuses the third diffusion space 431. Then, the ozone gas is supplied from the respective ozone-gas supply holes 53b (see, FIG. 7) in the gas supply surface 40a to the central area 10a of the process atmosphere through the plurality of third gas supply conduits 532 formed in the bottom surface of the third diffusion space 431. At this time, as shown in FIGS. 13(a), 13(b), and 13(d), a slight amount of the purge gas is supplied from the Sr-material supply line 610, the Ti-material gas supply line 620, and the purge-gas supply line 640, in order to prevent the ozone gas from entering the gas showerhead 4.

As a result, the ozone gas reaching the surface of the wafer W in the process atmosphere 10 reacts with the material gases which have been already adsorbed on the surface of the wafer W, by a heat energy from the stage heater, whereby an STO molecular layer is formed. After the ozone gas has been supplied for a predetermined time, the supply of the ozone gas is stopped. Then, as shown in FIGS. 13(c), 13(d), and FIG. 15, the purge gas is supplied form the ozone-gas supply line 630 and the purge-gas supply line 640, so that the ozone gas remaining in the process atmosphere 10 and the inside of the gas showerhead 4 is purged (ozone-gas purging step). Also a this time, as shown in FIGS. 13(a) and 13(b), a slight amount of the purge gas is flown from the first gas supply conduits 512 and the second gas supply conduits 522.

As shown in FIG. 13, one cycle including the aforementioned six steps is repeated predetermined times, e.g., 100 times. Thus, the multiple STO molecular layers are stacked, whereby deposition of an STO film having a predetermined film thickness is completed. As described above, in the material-gas supplying step, the material-gas purging step, the ozone-gas supplying step, and the ozone-gas purging step, it is effective that a slight amount of the purge gas is invariably made flow from the gas supply conduits in addition to the gas supply conduits through which a large amount of the purge gas actually flows. After the film deposition is finished, the supply of the various gases is stopped. Then, the table 3 on which the wafer W is placed is lowered to the transport opening, and the pressure in the process container 2 is returned to the value before the vacuum evacuation. Thereafter, the wafer W is unloaded by the external transport mechanism along the reverse path upon loading. In this manner, a series of the film deposition operations is completed.

In the present invention, the gas supply surface 40a is divided into the unit zones 401 formed of regular triangles of the same size. The Sr material gas (first process gas), the Ti material gas (second process gas), and the ozone gas (third process gas) are supplied from the three apexes of each regular triangle. Thus, the three gas supply holes 51b to 53b for jetting the first to third process gases exist in every regular triangle, and the three gas supply holes 51b to 53b are arranged with equal intervals therebetween. Thus, when a film is deposited by the so-called ALD method in which gas supply timings differ from each other, an excellent in-plane uniformity of a film thickness and of a film quality can be obtained.

In addition, even when the first to third process gases are simultaneously jetted as described above, it is possible to adsorb these gases in a uniform state. Thus, the arrangement of the gas supply holes 51b to 53b in this embodiment is not limited to the ALD method, but can be applied to a gas showerhead of a film deposition apparatus that deposits a film by simultaneously jetting the first to third gas by a CVD method.

In the above-described film deposition apparatus 1, there has been described the case in which an STO film is deposited by reacting the Sr material gas (first process gas) and Ti material gas (second process gas), which are used as material gases, with the ozone gas (third process gas) as an oxidizing gas. However, the kind of a film capable of being deposited by the film deposition apparatus 1 is not limited to the STO film. For example, a steam (water vapor), instead of the ozone gas described in the embodiment, may be employed as an oxidizing gas. Alternatively, the present invention may be applied to a process for depositing a barium titanate (BaTiO₃) film, by reacting a first process gas containing a barium compound and a second process gas containing a titanium compound, with an oxidizing gas as a third process gas.

1. A film deposition apparatus comprising:
a process container;
a table on which a substrate can be placed, the table being disposed in the process container; and
a gas showerhead disposed so as to be opposed to the table, the gas showerhead including a gas supply surface having a first gas supply hole for supplying a first process gas, a second gas supply hole for supplying a second process gas, and a third gas supply hole for supplying a third process gas;
wherein:
the gas supply surface is divided into unit zones formed of regular triangles of the same size, and the first gas supply hole, the second gas supply hole, and the third gas supply hole are disposed on respective three apexes of each regular triangle constituting the unit zone; and
the first process gas, the second process gas, and the third process gas differ from each other, and a film is deposited on a surface of the substrate by reacting the first process gas, the second process gas, and the third process gas with each other.

2. The film deposition apparatus according to claim 1, wherein:
the first process gas supplied from the first gas supply hole contains a strontium compound;
the second process gas supplied from the second gas supply hole contains a titanium compound;
the third process gas supplied from the third gas supply hole is an oxidizing gas reactable with the strontium compound and the titanium compound; and
the film to be deposited on the surface of the substrate is made of strontium titanate.

3. The film deposition apparatus according to claim 2, wherein
the oxidizing gas is an ozone gas or a steam.

4. A film deposition method comprising the steps of:
placing a substrate on a table disposed in a process container; and
supplying gases from a gas showerhead disposed so as to be opposed to the table, the gas showerhead being divided into unit zones formed of regular triangles of the same size, with a first gas supply hole, a second gas supply hole, and a third gas supply hole being disposed on respective three apexes of each regular triangle constituting the unit zone;
wherein:
the step of supplying gases includes a first process-gas supplying step for supplying the first process gas, a second process-gas supplying step for supplying the second process gas, and a third process-gas supplying step for supplying the third process gas; and
the first process gas, the second process gas, and the third process gas differ from each other, and a film is deposited on a surface of the substrate by reacting the first process gas, the second process gas, and the third process gas with each other.

5. The film deposition method according to claim 4, wherein:
the first process gas supplied in the first process-gas supplying step contains a strontium compound;
the second process gas in the second process-gas supplying step contains a titanium compound;
the third process gas supplied in the third process-gas supplying step is an oxidizing gas reactable with the strontium compound and the titanium compound; and
the film made of strontium titanate is deposited on the surface of the substrate.

6. The film deposition method according to claim 5, wherein
the oxidizing gas is an ozone gas or a steam.

7. A storage medium storing a computer program for causing a film deposition apparatus to perform a film deposition method that comprises the steps of:
placing a substrate on a table disposed in a process container; and
supplying gases from a gas showerhead disposed so as to be opposed to the table, the gas showerhead being divided into unit zones formed of regular triangles of the same size, with a first gas supply hole, a second gas supply hole, and a third gas supply hole being disposed on respective three apexes of each regular triangle constituting the unit zone;
wherein:
the step of supplying gas includes a first process-gas supplying step for supplying the first process gas, a second process-gas supplying step for supplying the second process gas, and a third process-gas supplying step for supplying the third process gas; and
the first process gas, the second process gas, and the third process gas differ from each other, and a film is deposited on a surface of the substrate by reacting the first process gas, the second process gas, and the third process gas with each other.

8. A gas supply apparatus comprising:
a first introduction port for introducing a first process gas;
a second introduction port for introducing a second process gas;
a third introduction port for introducing a third process gas;
a first gas supply hole for supplying the first process gas introduced from the first introduction port to a substrate;
a second gas supply hole for supplying the second process gas introduced from the second introduction port to the substrate;
a third gas supply hole for supplying the third process gas introduced from the third introduction port to the substrate; and
a gas conduit structure part configured such that the first process gas introduced from the first introduction port, the second process gas introduced from the second introduction port, the third process gas introduced from the third introduction port, are respectively jetted from the first gas supply hole, the second gas supply hole, and the third gas supply hole, independently;
wherein:
the first gas supply hole, the second gas supply hole, and the third gas supply hole are disposed in a gas supply surface;
the gas supply surface is divided into unit zones formed of regular triangles of the same size, and the first gas supply hole, the second gas supply hole, and the third gas supply hole are disposed on respective three apexes of each regular triangle constituting the unit zone; and
the first process gas, the second process gas, and the third process gas differ from each other, and a film is deposited on a surface of the substrate by reacting the first process gas, the second process gas, and the third process gas with each other.
